(19) United States
(12) Patent Application Publication
(10) Pub. No.: US 2026/0101597 A1
(43) Pub. Date: Apr. 9, 2026

(54) SEMICONDUCTOR DEVICES AND METHODS OF FORMATION

(71) Applicant: Taiwan Semiconductor Manufacturing Company, Ltd., Hsinchu (TW)

(72) Inventors: Yi-Hsuan WANG, Hsinchu City (TW); Cheng-Yu HUANG, Hsinchu (TW); Wei-Chieh CHIANG, Yuanlin Township (TW); Keng-Yu CHOU, Kaohsiung City (TW); Chun-Hao CHUANG, Hsinchu City (TW); Wen-Hau WU, New Taipei City (TW); Chih-Kung CHANG, Zhudong Township (TW)

(21) Appl. No.: 18/905,428

(22) Filed: Oct. 3, 2024

(51) Int. Cl. H01L 27/146

(52) U.S. Cl. CPC H10F 39/8053; H10F 39/024; H10F 39/8063

(57) ABSTRACT

A semiconductor optical sensor structure of a semiconductor device may include a photon absorption region and an anti-reflection structure (e.g., an anti-reflection film, a grating structure) above the photon absorption region. The anti-reflection structure may be tuned for the semiconductor optical sensor structure to achieve minimal reflection of incident light. In particular, attributes such as film thickness, refractive index, grating height, grating half-pitch, grating width, and/or grating spacing (among other examples) of the anti-reflection structure may be tuned to achieve a high percentage of transmittance of incident light (e.g., a high percentage of photons of the incident light that propagate through to the photon absorption region of the semiconductor optical sensor structure) and/or may be tuned to achieve destructive interference for incident light that is reflected.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a transfer gate, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2C are diagrams of example implementations of photodetector structures that may be included in a semiconductor device described herein.

FIGS. 3A-3H are diagrams of an example implementation of forming a semiconductor device described herein.

FIG. 4 is a diagram of an example implementation of a photodetector structure that may be included in a semiconductor device described herein.

FIGS. 5A-5C are diagrams of an example implementation of forming a semiconductor device described herein.

FIG. 6 is a diagram of an example implementation of a photodetector structure that may be included in a semiconductor device described herein.

FIG. 7 is a diagram of an example implementation of a photodetector structure that may be included in a semiconductor device described herein.

FIGS. 8A and 8B are diagrams of example implementations of photodetector structures that may be included in a semiconductor device described herein.

FIG. 9 is a diagram of an example of a portion of a semiconductor device described herein.

FIG. 10 is a diagram of example implementation of a portion of a pixel sensor array of a semiconductor device described herein.

FIGS. 11A-11F are diagrams of an example implementation of forming a semiconductor device described herein.

FIG. 12 is a diagram of an example implementation of a portion of a pixel sensor array of a semiconductor device described herein.

FIGS. 13A-13D are diagrams of an example implementation of forming a semiconductor device described herein.

FIGS. 14A-14E are diagrams of additional example implementations of a portion of a pixel sensor array of a semiconductor device described herein.

FIG. 15 is a flowchart of an example process associated with forming a semiconductor device described herein.

FIG. 16 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Performance of a semiconductor optical sensor structure (e.g., a pixel sensor, a photodetector) may be quantified in terms of quantum efficiency (QE). Quantum efficiency is expressed as a ratio or percentage and represents the efficiency with which photons of incident light are converted into photoelectrons (electrons generated by the absorption of the photons) within the semiconductor optical sensor structure. In other words, quantum efficiency quantifies how efficient a semiconductor optical sensor structure is at converting incoming photons into usable electrical signals. Furthermore, quantum efficiency directly affects the sensitivity performance of the pixel sensor structure. Specifically, the greater the quantum efficiency of the semiconductor optical sensor structure, the greater the sensitivity of the semiconductor optical sensor structure, and thus the greater the low-light performance and/or the lower the modulation transfer function (MTF—a characterization of optical contrast) that can be achieved by the semiconductor optical sensor structure.

Reflection of incident light is a contributor to reduced quantum efficiency in a semiconductor optical sensor structure. The greater the amount of incident light that is reflected away from the semiconductor optical sensor structure, the lesser the percentage of photons of the incident light that is converted into photoelectrons (and thus, the lower the quantity efficiency of the semiconductor optical sensor structure). Thus, reflection of incident light can lower the sensitivity and/or can increase the MTF (which results in lower contrast) of the semiconductor optical sensor structure.

Reflected incident light can also contribute degraded performance of other semiconductor optical sensor structures in that reflected incident light can result in optical crosstalk that interferes with the operation of the other semiconductor optical sensor structures. Optical crosstalk occurs when incident light directed toward a semiconductor optical sensor structure is redirected (usually by unwanted reflection) and absorbed by another semiconductor optical sensor structure. Optical crosstalk can cause color mixing between semiconductor optical sensor structures, which can lead to color inaccuracies in images and/or video generated based on the electrical signals generated by the semiconductor optical sensor structures.

In some implementations described herein, a semiconductor optical sensor structure of a semiconductor device may include a photon absorption region and an anti-reflection structure (e.g., an anti-reflection film, a grating structure) above the photon absorption region. The anti-reflection structure is included to reduce reflection of incident light for the semiconductor optical sensor structure. Thus, the anti-reflection structure may increase the quantum efficiency of the semiconductor optical sensor structure and/or may reduce the amount of optical crosstalk between the semiconductor optical sensor structure and other semiconductor optical sensor structures in the semiconductor device. The increased quantum efficiency may enable increased sensitivity, decreased MTF (and thus, increased contrast), and/or increased low-light performance to be achieved for the semiconductor optical sensor structure.

The anti-reflection structure may be tuned for the semiconductor optical sensor structure to achieve minimal reflection of incident light. In particular, attributes such as film thickness, refractive index, grating height, grating half-pitch, grating width, and/or grating spacing (among other examples) of the anti-reflection structure may be tuned to achieve a high percentage of transmittance of incident light (e.g., a high percentage of photons of the incident light that propagate through to the photon absorption region of the semiconductor optical sensor structure) and/or may be tuned to achieve destructive interference for incident light that is reflected. The high percentage of transmittance and destructive interference of reflected incident light enables a low percentage of reflection of incident light to be achieved for the semiconductor optical sensor structure.

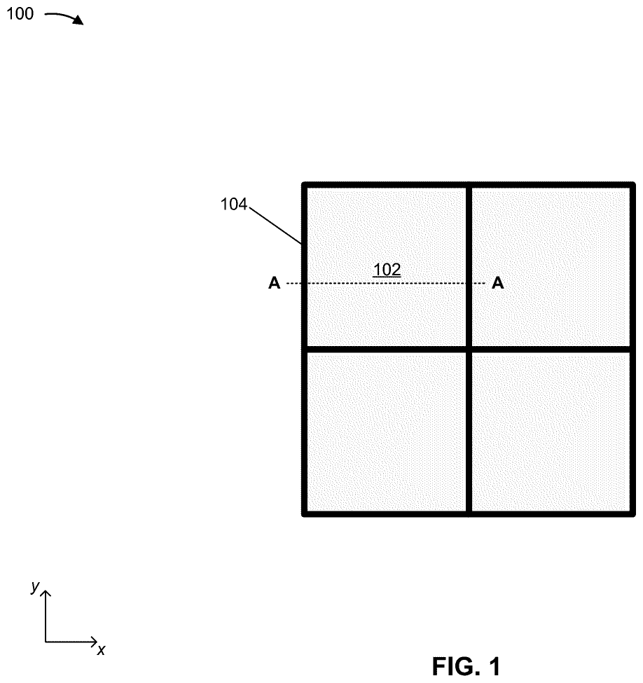

FIG. 1 is a diagram of an example semiconductor device 100 described herein. FIG. 1 illustrates a top view of the semiconductor device 100 (or a portion thereof). The semiconductor device 100 may include an image sensor device, an automotive sensor (e.g., a light detection and ranging (LIDAR) sensor), an infrared detector, a time of flight (ToF) sensor, and/or another semiconductor device that includes one or more photodetector structures 102.

As shown in FIG. 1, the photodetector structures 102 may be arranged in a grid in the semiconductor device 100. However, other arrangements and quantities of photodetector structures 102 are within the scope of the present disclosure. The photodetector structures 102 may be configured to generate an electrical signal (e.g., a photocurrent) by converting photons of incident light to electrons through the photoelectric effect.

An isolation structure 104 (e.g., a deep trench isolation (DTI) structure, a shallow trench isolation (STI) structure) may be included around the photodetector structures 102 to reduce optical crosstalk between the photodetector structures 102. The isolation structure 104 may include a plurality of interconnected segments that laterally surround the photodetector structures 102.

As indicated above, FIG. 1 is provided as an example. Other examples may differ from what is described with regard to FIG. 1.

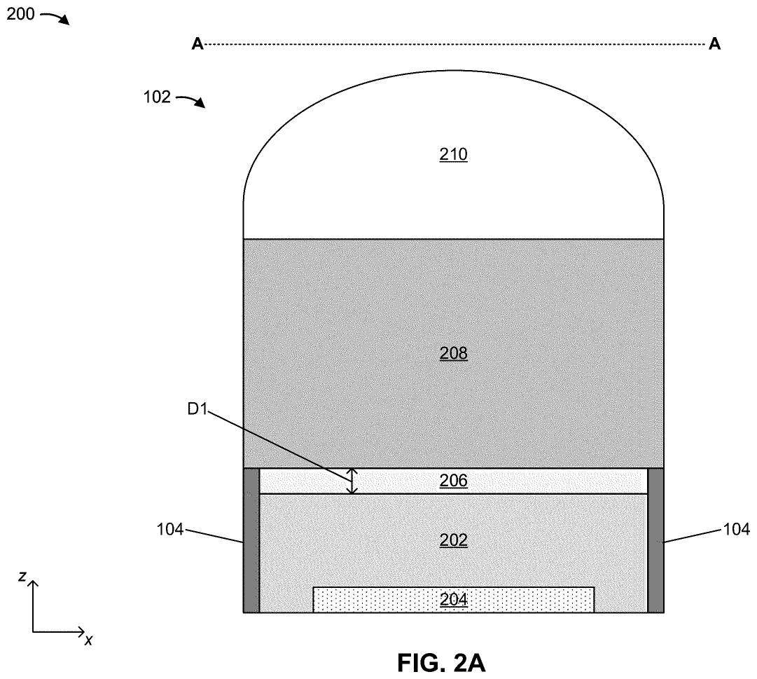

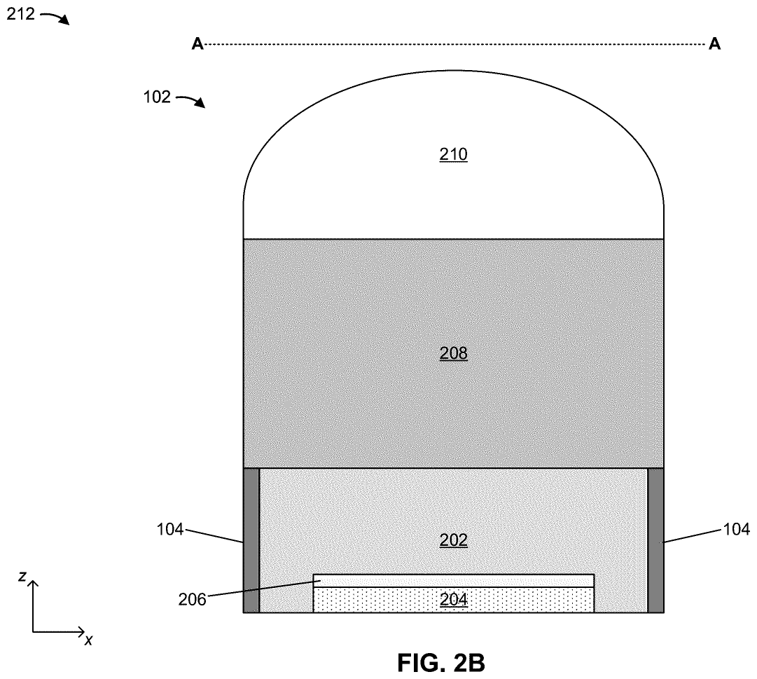

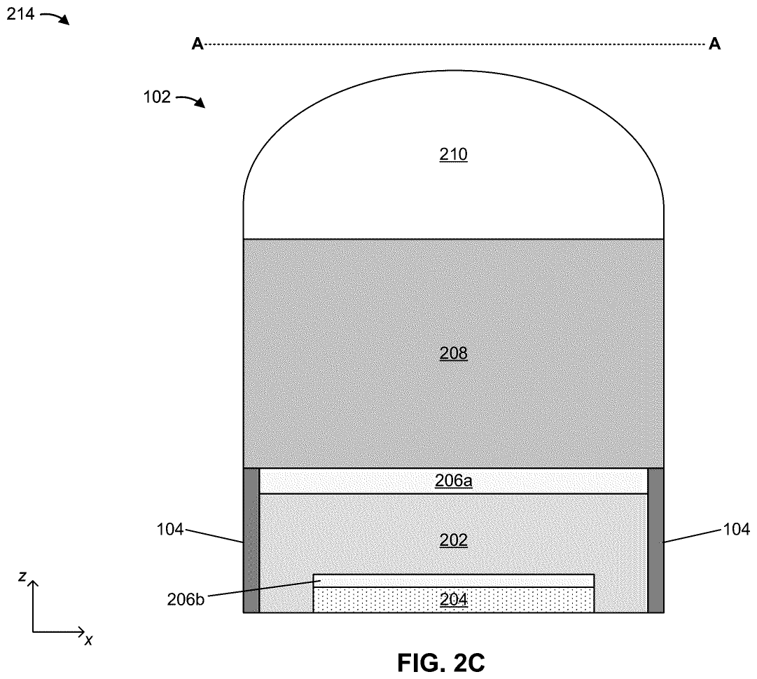

FIGS. 2A-2C are diagrams of example implementations of photodetector structures 102 that may be included in the semiconductor device 100 described herein. In the example implementations illustrated in FIGS. 2A-2C, a photodetector structure 102 includes one or more anti-reflection films that function as anti-reflection structures for the photodetector structure 102. In other words, the anti-reflection film(s) increase transmittance and/or reduce reflectance of incident light through destructive interference of reflected waves of incident light. In this way, the anti-reflection film(s) in the example implementations in FIGS. 2A-2C increase the quantum efficiency of the photodetector structures 102.

FIG. 2A illustrates a cross-section view of an example implementation 200 of a photodetector structure 102 along the line A-A in FIG. 1. As shown in FIG. 2A, the photodetector structure 102 includes, or may be included in, a semiconductor layer 202. The semiconductor layer 202 may correspond to a substrate layer of the semiconductor device 100. Alternatively, the semiconductor layer 202 may correspond to a top semiconductor layer of a silicon-on-insulator (SOI) substrate on which the semiconductor device 100 was formed. The semiconductor layer 202 may include a semiconductor material such as silicon (Si), undoped silicon, silicon doped with p-type dopants (e.g., boron (B) and/or gallium (Ga), among other examples), silicon doped with n-type dopants (e.g., arsenic (As) and/or phosphorous (P), among other examples), and/or another semiconductor material.

The photodetector structure 102 includes a photon absorption region 204 in the semiconductor layer 202. The photon absorption region 204 may be configured to absorb photons of incident light and convert the photons to electrons through the photoelectric effect. The photons interact with electron-hole pairs in the photon absorption region 204. The interaction causes electrons and holes to be separated and to migrate toward opposing collection regions (not shown) in the semiconductor layer 202, resulting in the generation of an electric field (e.g., a built-in electric field). The accumulation of holes and the accumulation of electrons at the collection regions cause a photocurrent to be generated. The magnitude of the photocurrent may be proportional to the amount of photons that is collected in the photon absorption region 204. Accordingly, the photocurrent that is generated may be an indication of the intensity of the incident light.

The photon absorption region 204 may include a semiconductor material. The semiconductor material of the photon absorption region 204 may be the same as the semiconductor material of the semiconductor layer 202. Additionally and/or alternatively, the semiconductor material of the photon absorption region 204 and the semiconductor material of the semiconductor layer 202 may be different semiconductor materials. Examples of semiconductor materials for the photon absorption region 204 include germanium (Ge), germanium tin (GeSn), silicon germanium (SiGe), indium gallium arsenide (InGaAs), and/or gallium arsenide (GaAs), among other examples.

The isolation structure 104 may laterally surround the photon absorption region 204 to protect the photon absorption region 204 from crosstalk from other photodetector structures 102 in the semiconductor device 100. In some implementations, the top surfaces of the isolation structure extend above the top surface of the photon absorption region 204. In some implementations, the isolation structure 104 includes one or more dielectric materials such as a silicon oxide (SiOₓ), a silicon nitride (SiₓN_{y}), a silicon carbide (SiCₓ), a silicon carbon nitride (SiCN), and/or a silicon oxynitride (SiON), among other examples. In some implementations the isolation structure 104 includes one or more metal materials such as tungsten (W), ruthenium (Ru), cobalt (Co), and/or nickel (Ni), among other examples.

As further shown in FIG. 2A, the photodetector structure 102 includes an anti-reflection film 206 on the semiconductor layer 202. The anti-reflection film 206 is positioned above and/or over the photon absorption region 204 such that photons of incident light pass through the anti-reflection film 206 toward the photon absorption region 204. The anti-reflection film 206 is a thin film that is included to reduce reflection of incident light away from the photon absorption region 204 so that a high quantum efficiency can be achieved for the photodetector structure 102. In some implementations, the anti-reflection film 206 is recessed in between the isolation structures 104, as shown in the example in FIG. 2A. Alternatively, the anti-reflection film 206 may be located at a higher z-direction position in the semiconductor device 100 than the tops of the isolation structure 104.

As further shown in FIG. 2A, an optical spacer structure 208 may be included above the photon absorption region 204. In some implementations, the optical spacer structure 208 is included on the anti-reflection film 206. The optical spacer structure 208 may include a polymer material that is transmissive to a particular wavelength or a particular wavelength range of incident light (e.g., a near infrared light wavelength range), such as polymethyl methacrylate (PMMA), polycarbonate, polyethylene (PE), polyvinylidene fluoride (PVDF), or another suitable polymer material, among other examples. Alternatively, the optical spacer structure 208 may include a resin material that is transmissive to infrared light, such as epoxy resin or another suitable resin material, among other examples. Alternatively, the optical spacer structure 208 may include an organic material that is transmissive to near infrared light, such as a cyclo-olefin copolymer (COC), cyclo-olefin polymer (COP), or another suitable organic material, among other examples.

The anti-reflection film 206 may include a material having a refractive index that is different than the refractive index of the semiconductor layer 202 for the wavelength range of incident light that is to be sensed by the photodetector structure 102. In particular, the anti-reflection film 206 may include a material having a refractive index that is less than the refractive index of the semiconductor layer 202. For example, the semiconductor layer 202 may include silicon (having a refractive index of approximately 3.4 to approximately 4.0, depending on the wavelength of incident light) and the anti-reflection film 206 may include tantalum oxide (TaₓO_{y} such as Ta₂O₅—having a refractive index of approximately 2.0 to approximately 2.3, depending on the wavelength of incident light). Other examples of materials for the anti-reflection film 206 include dielectric materials having high optical transparency such as silicon oxide (SiOₓ such as SiO₂—having a refractive index of approximately 1.4 to approximately 2.3, depending on the wavelength of incident light), silicon oxynitride (SiON), and/or a high dielectric constant (high-k) dielectric material having a dielectric constant greater than approximately 3.9, among other examples. The lesser refractive index of the material of the anti-reflection film 206 reduces reflectance at the interface between the anti-reflection film 206 and the semiconductor layer 202, which increases the percentage of photons of incident light that propagate into the semiconductor layer 202 to the photon absorption region 204. However, in other implementations, the refractive index of the material of the anti-reflection film 206 may be less than the refractive index of the material of the semiconductor layer 202.

As further shown in FIG. 2A, the anti-reflection film 206 may have a z-direction thickness (indicated in FIG. 2A as dimension D1), which may be selected to achieve destructive interference for waves of incident light that are reflected at the interface between the anti-reflection film 206 and the semiconductor layer 202. The destructive interference destroys or cancels out the waves of incident light that are reflected, which prevents (or reduces the likelihood of) those waves from propagating toward other photodetector structures 102 and causing optical crosstalk.

The z-direction thickness of the anti-reflection film 206 may be based on the wavelength (or wavelength range) of incident light that is to be sensed by the photodetector structure 102. Moreover, the z-direction thickness of the anti-reflection film 206 may be based on the effective refractive index of the semiconductor layer 202 and the anti-reflection film 206. For example, the z-direction thickness of the anti-reflection film 206 may be represented as:

$$d = \frac{λ}{4 {n}_{e}} \times m$$

where d corresponds to the z-direction thickness of the anti-reflection film 206; λ corresponds to the wavelength of the incident light; nₑ corresponds to the effective refractive index of a combination of the semiconductor layer 202, the anti-reflection film 206, and the optical spacer structure 208; and m is an integer coefficient such as ±1, ±2, ±3, or so on. In some implementations, m is an odd number if the refractive index of the optical spacer structure 208 is less than the refractive index of the anti-reflection film 206, and/or if the refractive index of the anti-reflection film 206 is less than the refractive index of the semiconductor layer 202. In some implementations, m is an even number if the refractive index of the optical spacer structure 208 is less than the refractive index of the anti-reflection film 206, and/or if the refractive index of the anti-reflection film 206 is greater than the refractive index of the semiconductor layer 202.

If the z-direction thickness of the anti-reflection film 206 satisfies the formula above, a high likelihood of destructive interference may be achieved for waves of incident light that are reflected at the interface between the anti-reflection film 206 and the semiconductor layer 202. Destructive interference is achieved in that the anti-reflection film 206 causes reflected waves of light having approximately the same amplitude as the incident light to be phase shifted relative to the waves of incident light. In particular, the reflected waves of light may have a phase that is shifted approximately 180 degrees relative to the phase of the waves of incident light, and this 180-degree phase shift causes the waves of incident light and the reflected waves of light to cancel out. In other words, the amplitude of the resulting wave from the combination of a wave of incident light and a reflected wave of light is substantially zero due to the 180-degree phase shift.

The effective refractive index of the semiconductor layer 202 and the anti-reflection film 206 is a value that represents the overall optical behavior of the combination of the semiconductor layer 202 and the anti-reflection film 206. The effective refractive index of the semiconductor layer 202 and the anti-reflection film 206 may be based on the refractive index of the material of the semiconductor layer 202, the refractive index of the material of the anti-reflection film 206, interference effects between the semiconductor layer 202 and the anti-reflection film 206, and/or other properties of the semiconductor layer 202 and/or of the anti-reflection film 206.

If different photodetector structures 102 in the semiconductor device 100 are configured to sense incident light of different wavelengths, the z-direction thicknesses of the anti-reflection films 206 for the photodetector structures 102 may be different. Thus, the semiconductor device 100 may include a plurality of photodetector structures 102 that include anti-reflection films 206, and the anti-reflection films 206 may have different z-direction thicknesses.

For example, a first photodetector structure 102 of the semiconductor device 100 may be configured to sense a first wavelength of incident light, and a second photodetector structure 102 of the semiconductor device 100 may be configured to sense a second wavelength of incident light that is different than the first wavelength. Accordingly, the respective z-direction thicknesses of the anti-reflection films 206 of the first and second photodetector structures 102 may be different z-direction thicknesses. As an example, if the first wavelength is less than the second wavelength, the z-direction thickness of the anti-reflection film 206 of the first photodetector structure 102 may be greater than the z-direction thickness of the anti-reflection film 206 of the second photodetector structure 102.

As another example, a first photodetector structure 102 of the semiconductor device 100 may be configured to sense a first wavelength range of incident light, and a second photodetector structure 102 of the semiconductor device 100 may be configured to sense a second wavelength range of incident light that is different than the first wavelength range. In some implementations, the first wavelength range and the second wavelength range are different in that the first wavelength range and the second wavelength range do not overlap (meaning no wavelength in the first wavelength range is included in the second wavelength range, and no wavelength range in the second wavelength range is included in the first wavelength range). In some implementations, the first wavelength range and the second wavelength range are different in that the first wavelength range and the second wavelength range only partially overlap. For example, a first subset of wavelengths in the first wavelength range is included in the second wavelength range, and a second subset of wavelengths in the first wavelength range is not included in the second wavelength range. In some implementations, the first wavelength range and the second wavelength range are different in that the first wavelength range is included within the second wavelength range, but the second wavelength range spans a broader wavelength range than the first wavelength range.

As shown in FIG. 2A, a micro-lens structure 210 having a convex surface may be included above the optical spacer structure 208. The convex surface may be a substantially convex curvature that extends away from the optical spacer structure 208 and/or the photon absorption region 204. The micro-lens structure 210 may include a polymer material that is transmissive to near infrared light, such as polymethyl methacrylate (PMMA), polycarbonate, polyethylene (PE), polyvinylidene fluoride (PVDF), or another suitable polymer material, among other examples. Alternatively, the micro-lens structure 210 may include a resin material that is transmissive to a particular wavelength or a particular wavelength range of incident light, such as epoxy resin or another suitable resin material, among other examples. Alternatively, the micro-lens structure 210 may include an organic material that is transmissive to near infrared light, such as a cyclo-olefin copolymer (COC), cyclo-olefin polymer (COP), or another suitable organic material, among other examples.

As shown in FIG. 2A, the optical spacer structure 208 may be located between the micro-lens structure 210 and the photon absorption region 204. In some implementations, the optical spacer structure 208 is configured to maintain a separation distance between a bottom surface of the micro-lens structure 210 and a top surface of the photon absorption region 204. The separation distance may alter a focal length of the micro-lens structure 210 and optimize a dispersion of light across a surface of the photon absorption region 204.

FIG. 2B illustrates a cross-section view of an example implementation 212 of a photodetector structure 102. As shown in FIG. 2A, the example implementation 212 of the photodetector structure 102 may include a similar combination and arrangement of layers and/or structures as the example implementation 200 of the photodetector structure 102. However, in the example implementation 212 of the photodetector structure 102, the anti-reflection film 206 is located on the photon absorption region 204 as opposed to on the surface of the semiconductor layer 202. The z-direction thickness of the anti-reflection film 206 in the example implementation 212 of the photodetector structure 102 may be selected based on the effective refractive index of the anti-reflection film 206 and the photon absorption region 204, additionally and/or alternatively to the wavelength (or wavelength range) of incident light that is to be sensed by the photodetector structure 102.

FIG. 2C illustrates a cross-section view of an example implementation 214 of a photodetector structure 102. As shown in FIG. 2C, the example implementation 214 of the photodetector structure 102 may include a similar combination and arrangement of layers and/or structures as the example implementation 200 of the photodetector structure 102. However, in the example implementation 214 of the photodetector structure 102, the photodetector structure 102 includes a plurality of anti-reflection films. For example, an anti-reflection film 206a may be included on the surface of the semiconductor layer 202. As another example, an anti-reflection film 206b may be included on the photon absorption region 204.

In some implementations, the anti-reflection film 206a and the anti-reflection film 206b have different z-direction thicknesses. For example, the anti-reflection film 206a may have a z-direction thickness that is based on the effective refractive index of the anti-reflection film 206a and the semiconductor layer 202, and the anti-reflection film 206b may have a z-direction thickness that is based on the effective refractive index of the anti-reflection film 206b and the photon absorption region 204. Additionally and/or alternatively, the anti-reflection film 206a and the anti-reflection film 206b may include different materials. For example, the anti-reflection film 206a may include tantalum oxide (TaₓO_{y} such as Ta₂O₅), and the anti-reflection film 206b may include silicon oxynitride (SiON). This enables the properties of the anti-reflection film 206a to be tuned for reducing reflections at the surface of the semiconductor layer 202, and enables the properties of the anti-reflection film 206b to be tuned for reducing reflections at the surface of the photon absorption region 204.

As indicated above, FIGS. 2A-2C are provided as examples. Other examples may differ from what is described with regard to FIGS. 2A-2C.

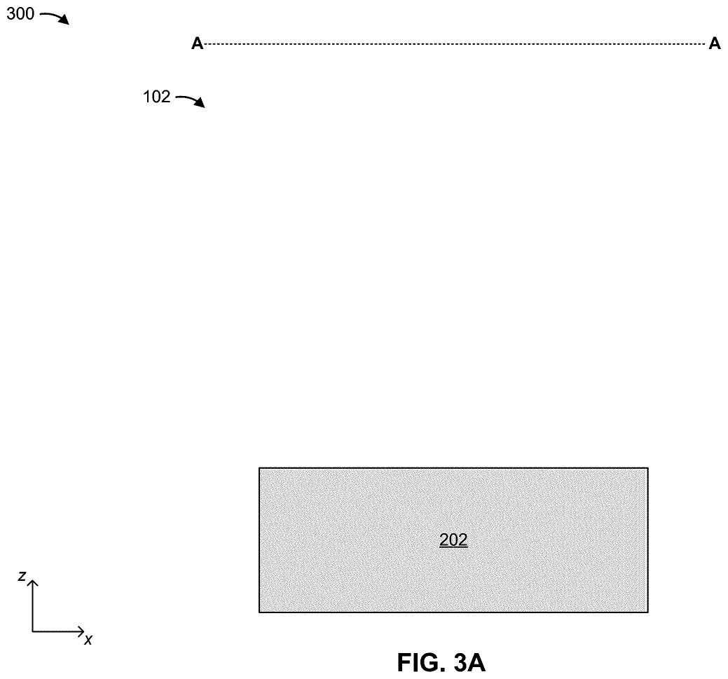

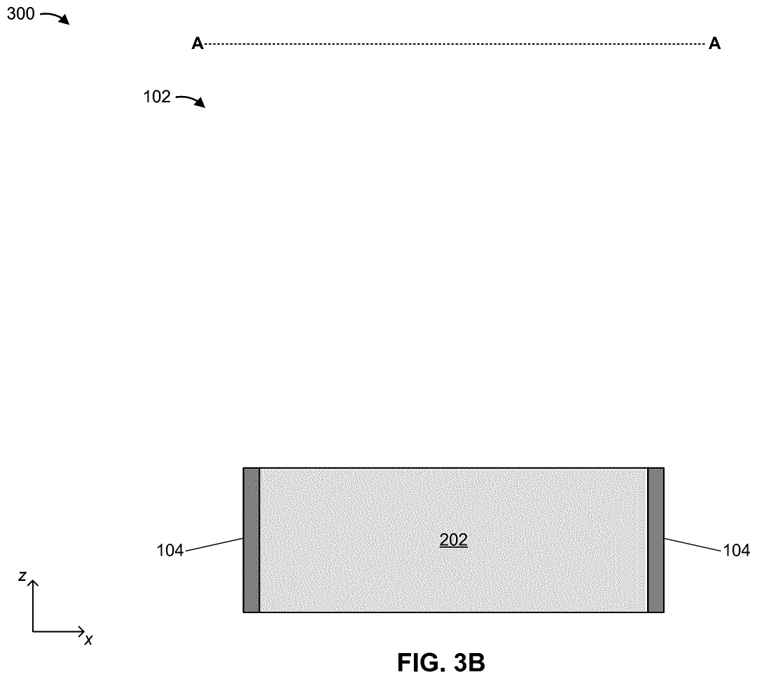

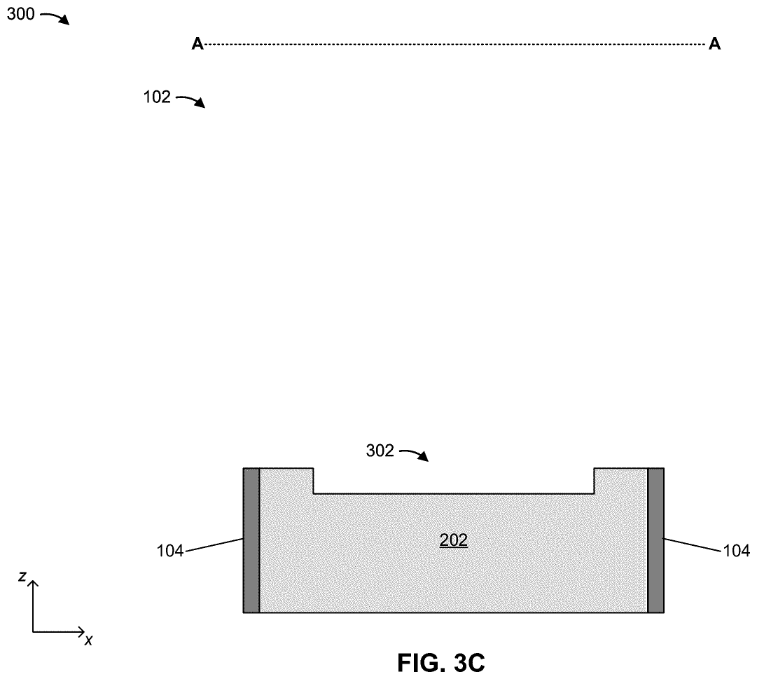

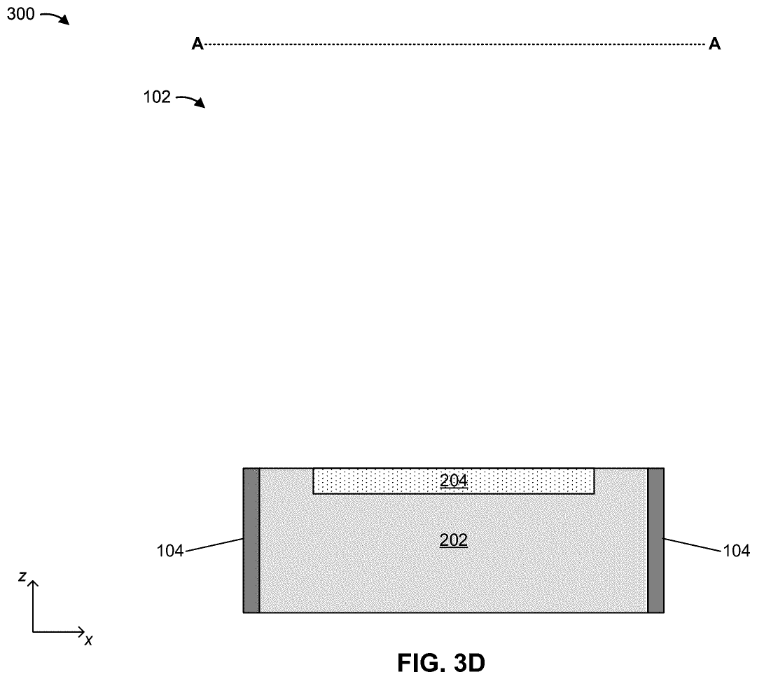

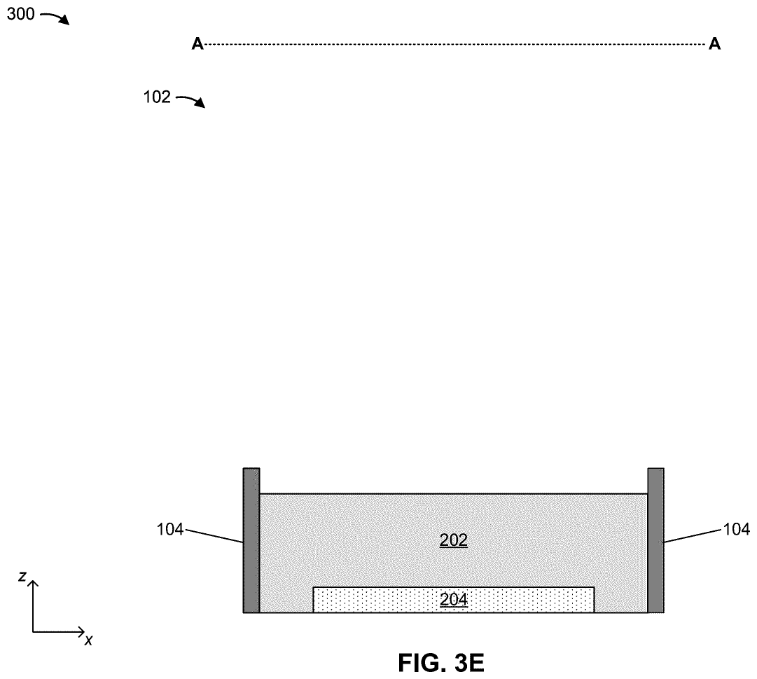

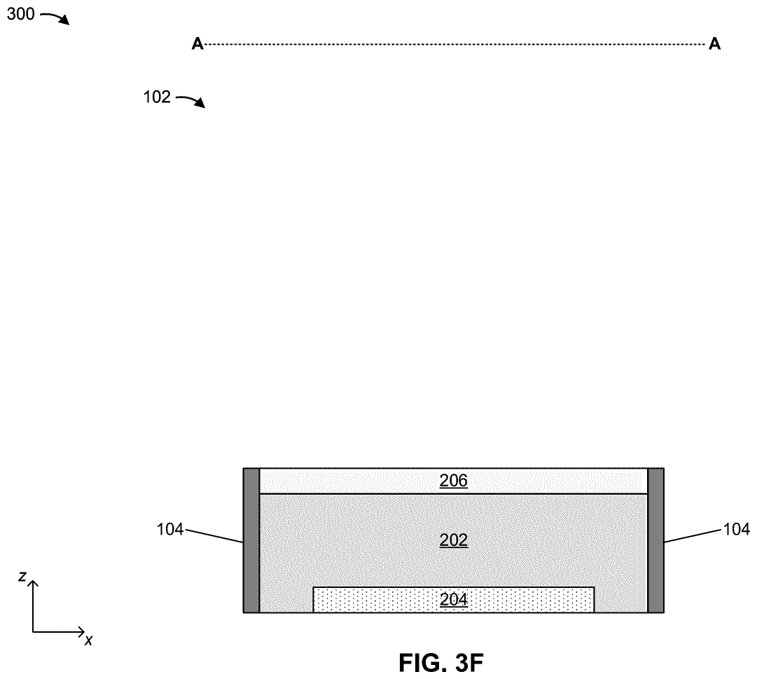

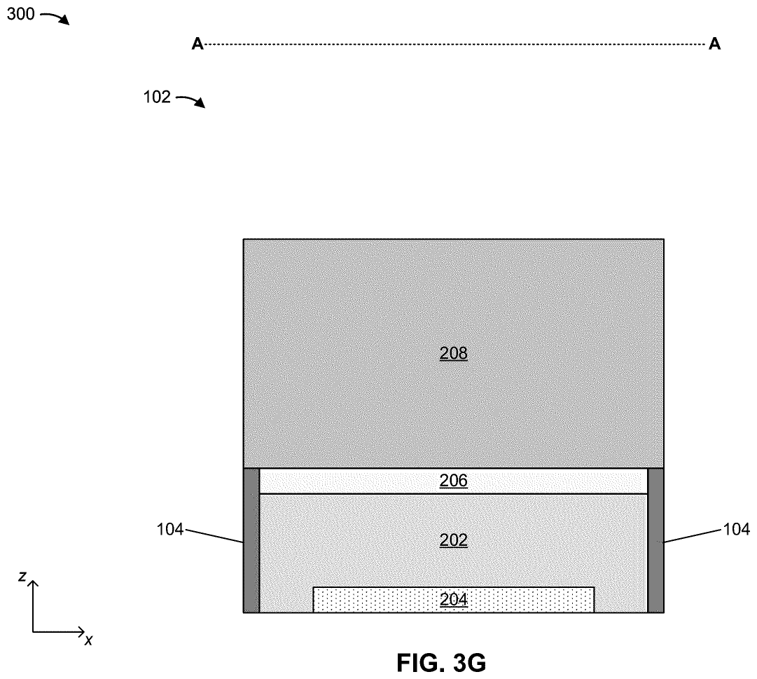

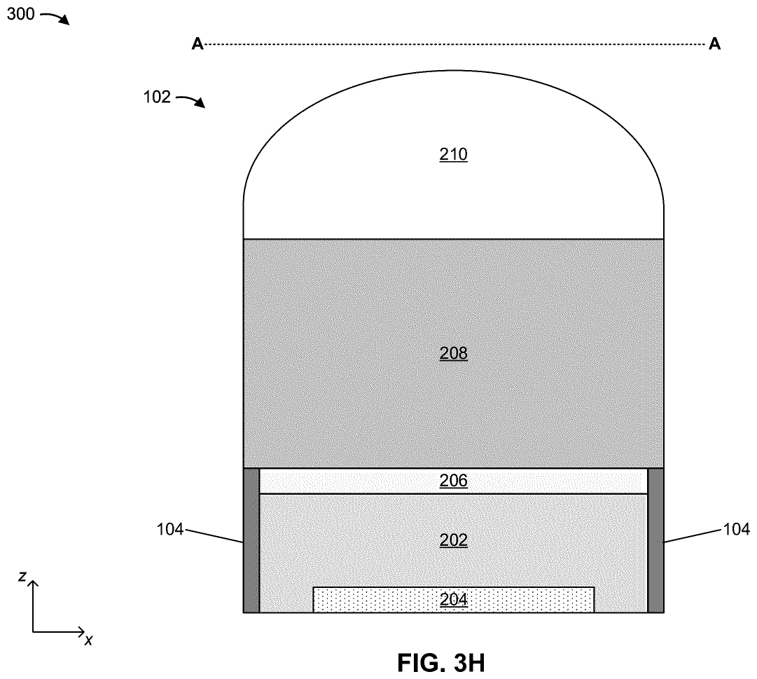

FIGS. 3A-3H are diagrams of an example implementation 300 of forming a semiconductor device 100 described herein. In particular, the example implementation 300 may include an example of forming one or more photodetector structures 102 of the semiconductor device 100. In some implementations, one or more of the semiconductor processing operations described in connection with FIGS. 3A-3H may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 3A, one or more of the semiconductor processing operations in the example implementation 300 may be performed in connection with the semiconductor layer 202. The semiconductor layer 202 may be provided as a semiconductor wafer, as part of an SOI wafer, or may be provided as another type of semiconductor work piece.

As shown in FIG. 3B, the isolation structures 104 may be formed in the semiconductor layer 202. To form the isolation structure 104, recesses (e.g., trenches) may be formed in the semiconductor layer 202, and the isolation structure 104 may be formed in the recesses.

In some implementations, a pattern in a photoresist layer is used to etch the semiconductor layer 202 to form the recesses. In these implementations, a deposition tool may be used to form the photoresist layer on the semiconductor layer 202 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 202 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 202 based on a pattern.

A deposition tool may be used to deposit the material of the isolation structure 104 in the recesses using a physical vapor deposition (PVD) technique, an atomic layer deposition (ALD) technique, a chemical vapor deposition (CVD) technique, an oxidation technique, and/or another suitable deposition technique. The isolation structure 104 may be deposited in one or more deposition operations and/or as one or more layers. In some implementations, a planarization tool may be used to perform a planarization operation (e.g., a chemical-mechanical planarization (CMP) operation) to planarize the isolation structure 104 after the isolation structure 104 is deposited.

As shown in FIGS. 3C and 3D, the photon absorption region 204 of a photodetector structure 102 may be formed in the semiconductor layer 202. For example, a recess 302 may be formed in the semiconductor layer 202 (as shown in FIG. 3C), and the photon absorption region 204 may be formed in the recess 302 (as shown in FIG. 3D). Alternatively, the photon absorption region 204 may be formed on the surface of the semiconductor layer 202, and additional material of the semiconductor layer 202 may be formed on the photon absorption region 204.

In some implementations, a pattern in a photoresist layer is used to etch the semiconductor layer 202 to form the recess 302. In these implementations, a deposition tool may be used to form the photoresist layer on the semiconductor layer 202 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 202 based on the pattern to form the recess 302. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 202 based on a pattern.

The photon absorption region 204 may be formed in the recess 302 (or on the surface of the semiconductor layer 202) by epitaxial growth. For example, a deposition tool may be used to deposit material of the photon absorption region 204, and a high-temperature annealing operation may be performed to cause the material to form a particular crystalline structure.

As shown in FIGS. 3E and 3F, the anti-reflective film 206 of the photodetector structure 102 may be formed in the semiconductor layer 202. For example, a recess may be formed in the semiconductor layer 202 (as shown in FIG. 3E), and the anti-reflective film 206 may be formed in the recess (as shown in FIG. 3F). Alternatively, the anti-reflective film 206 may be formed on the surface of the semiconductor layer 202. The anti-reflective film 206 (and the associated recess) may be formed in the back side of the semiconductor layer 202. Accordingly, after the photon absorption region 204 is formed in the front side of the semiconductor layer 202 (which may be vertically opposite the back side in the z-direction), the semiconductor device 100 may be flipped so that back side processing can be performed to form the anti-reflective film 206. Alternatively, both the photon absorption region 204 and the anti-reflective film 206 are formed in the front side (or in the back side) of the semiconductor layer 202.

In some implementations, a pattern in a photoresist layer is used to etch the semiconductor layer 202 to form the recess. In these implementations, a deposition tool may be used to form the photoresist layer on the semiconductor layer 202 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 202 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 202 based on a pattern.

A deposition tool may be used to deposit the anti-reflective film 206 using a PVD technique, an ALD technique, a CVD technique, an oxidation technique, and/or another suitable deposition technique. The anti-reflective film 206 may be deposited in one or more deposition operations. In some implementations, a planarization tool may be used to perform a planarization operation (e.g., a CMP operation) to planarize the anti-reflective film 206 after the anti-reflective film 206 is deposited.

The anti-reflective film 206 may be formed to a z-direction thickness (e.g., dimension D1) that is based on the wavelength (or wavelength range) of incident light that is to be sensed by the photodetector structure 102, and/or that is based on the effective refractive index of the semiconductor layer 202 and the anti-reflective film 206. In some implementations, a plurality of photodetector structures 102 are formed in and/or on the semiconductor layer 202. For example, a first photodetector structure 102 and a second photodetector structure 102 may be formed in and/or on the semiconductor layer 202. The first photodetector structure 102 and the second photodetector structure 102 may be configured to sense different wavelengths (or different wavelength ranges) of incident light, and/or may be formed to include anti-reflective films 206 formed of different materials (e.g., such that the effective refractive indexes for the first photodetector structure 102 and the second photodetector structure 102 are different). For example, the first photodetector structure 102 may be configured to sense a near infrared wavelength range of incident light, and the second photodetector structure 102 may be configured to sense a visible light wavelength range of incident light. Accordingly, a first anti-reflective film 206 having a different first z-direction thickness may be formed for the first photodetector structures 102, and a first anti-reflective film 206 having a different second z-direction thickness may be formed for the second photodetector structures 102, where the first z-direction thickness and the second z-direction thickness are different z-direction thicknesses.

Additionally and/or alternatively to forming the anti-reflective film 206 on the semiconductor layer 202, an anti-reflective film 206 may be formed in the recess 302, and the photon absorption region 204 may be formed on the anti-reflection film 206. In this way, an anti-reflection film 206a may be included on the back side of the semiconductor layer 202, and another anti-reflection film 206b may be included in the front side of the semiconductor layer 202.

In some implementations, a first photodetector structure 102 may be formed to include an anti-reflective film 206 on the semiconductor layer 202 above the photon absorption region 204 of the first photodetector structure 102, a second photodetector structure 102 may be formed to include an anti-reflective film 206 on the photon absorption region 204 of the second photodetector structure 102, and/or a third photodetector structure 102 may be formed to include an anti-reflective film 206a on the semiconductor layer 202 above the photon absorption region 204 of the third photodetector structure 102 and an anti-reflective film 206b on the photon absorption region 204 of the third photodetector structure 102.

As shown in FIG. 3G, an optical spacer structure 208 of the photodetector structure 102 may be formed above and/or on the anti-reflection film 206. In some implementations, the optical spacer structure 208 is formed separately and transferred to the photodetector structure 102, where the optical spacer structure 208 is placed or provided on the anti-reflection film 206 above the photon absorption region 204. In some implementations, a deposition tool is used to deposit the optical spacer structure 208 using a PVD technique, an ALD technique, a CVD technique, an oxidation technique, and/or another suitable deposition technique. In some implementations, a deposition tool is used to dispense the material of the optical spacer structure 208 and cure the material to form the optical spacer structure 208. The optical spacer structure 208 may be deposited in one or more deposition operations and/or as one or more layers. In some implementations, a planarization tool may be used to perform a planarization operation (e.g., a CMP operation) to planarize the optical spacer structure 208 after the optical spacer structure 208 is formed.

As shown in FIG. 3H, a micro-lens structure 210 of the photodetector structure 102 may be formed above and/or on the optical spacer structure 208. In some implementations, the micro-lens structure 210 is formed separately and transferred to the photodetector structure 102, where the micro-lens structure 210 is placed or provided on the optical spacer structure 208 above the photon absorption region 204. In some implementations, a deposition tool is used to deposit the micro-lens structure 210 using a PVD technique, an ALD technique, a CVD technique, an oxidation technique, and/or another suitable deposition technique. In some implementations, a deposition tool is used to dispense the material of the micro-lens structure 210 and cure the material to form the micro-lens structure 210.

As indicated above, FIGS. 3A-3H are provided as an example. Other examples may differ from what is described with regard to FIGS. 3A-3H.

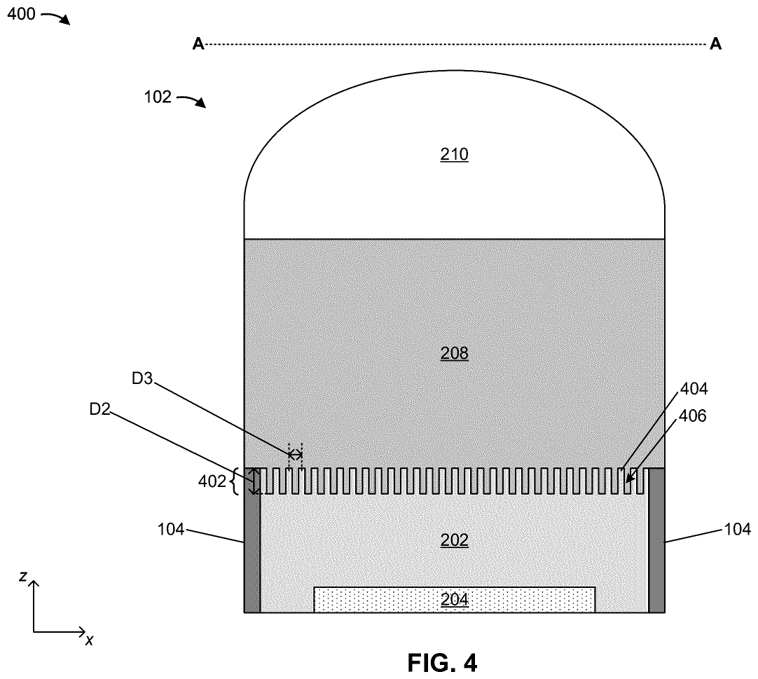

FIG. 4 is a diagram of an example implementation 400 of a photodetector structure 102 that may be included in the semiconductor device 100 described herein. As shown in FIG. 4, the example implementation 400 of the photodetector structure 102 includes a similar combination and/or arrangement of layers and/or structures as the example implementation 200 of the photodetector structure 102 in FIG. 2A. However, in the example implementation 400 of the photodetector structure 102 in FIG. 4, the anti-reflection film(s) are omitted and a grating structure 402 is instead included in the surface (e.g., the back side surface) of the semiconductor layer 202. The grating structure 402 is included above the photon absorption region 204 of the photodetector structure 102 and functions as an anti-reflection structure for the photodetector structure 102. In other words, the grating structure 402 increases transmittance and/or reduces reflectance of incident light through destructive interference of reflected waves of incident light. In this way, the grating structure 402 in the example implementation 400 in FIG. 4 increases the quantum efficiency of the photodetector structures 102.

As shown in FIG. 4, the grating structure 402 is positioned above and/or over the photon absorption region 204 such that photons of incident light pass through the grating structure 402 toward the photon absorption region 204. The grating structure 402 may correspond to a portion of the semiconductor layer 202 that includes a plurality of gratings 404 that are spaced apart by recesses 406 in the back side surface of the semiconductor layer 202. The gratings 404 may be periodic, semi-periodic, and/or aperiodic. In the example in FIG. 4, the gratings 404 are shown to have approximately rectangular cross-sectional profiles. However, the gratings 404 may have approximately triangular cross-sectional profiles, approximately square cross-sectional profiles, and/or other cross-sectional profiles.

The gratings 404 (or a subset thereof) may each have a z-direction height (indicated in FIG. 4 as dimension D2) relative to the bottom of the recesses 406, which may be selected to achieve destructive interference for waves of incident light that are reflected at the interface between the grating structure 402 and the semiconductor layer 202. The destructive interference destroys or cancels out the waves of incident light that are reflected, which prevents (or reduces the likelihood of) those waves from propagating toward other photodetector structures 102 and causing optical crosstalk.

The z-direction height of the gratings 404 (or a subset thereof) may be based on the wavelength (or wavelength range) of incident light that is to be sensed by the photodetector structure 102. Moreover, the z-direction height of the gratings 404 may be based on the effective refractive index of the semiconductor layer 202 and the portions of the optical spacer structure 208 that extend into the recesses 406 that are located between adjacent pairs of gratings 404. For example, the z-direction height of the gratings 404 may be represented as:

$$h = \frac{λ}{4 {n}_{e}} \times ( 2 m + 1 )$$

where h corresponds to the z-direction height of the gratings 404, λ corresponds to the wavelength of the incident light, nₑ corresponds to the effective refractive index of the semiconductor layer 202 and the optical spacer structure 208, and m is an integer coefficient such as ±1, ±2, ±3, or so on. If the z-direction height of the gratings 404 satisfies the formula above, a high likelihood of destructive interference may be achieved for waves of incident light that are reflected at the interface between the gratings 404 and the optical spacer structure 208.

The effective refractive index of the semiconductor layer 202 and the optical spacer structure 208 may be based on the refractive index of the material of the semiconductor layer 202 the refractive index of the material of the optical spacer structure 208. Moreover, the effective refractive index of the semiconductor layer 202 and the optical spacer structure 208 may be based on the size of the gratings 404 and/or the size of the recesses 406. The greater the lateral (e.g., x-direction) width of the gratings 404, the lesser the lateral (e.g., x-direction) width of the recesses 406 for the constant half-pitch between adjacent gratings 404 (indicated in FIG. 4 as dimension D3). Thus, the ratio of material of the semiconductor layer 202 in the gratings 404 to the material of the optical spacer structure 208 in the recesses 406 changes if the lateral (e.g., x-direction) width of the gratings 404 is increased and the lateral (e.g., x-direction) width of the recesses 406 is decreased. Similarly, the ratio of material of the semiconductor layer 202 in the gratings 404 to the material of the optical spacer structure 208 in the recesses 406 changes if the lateral (e.g., x-direction) width of the gratings 404 is decreased and the lateral (e.g., x-direction) width of the recesses 406 is increased. Changes to the ratio of material of the semiconductor layer 202 in the gratings 404 to the material of the optical spacer structure 208 in the recesses 406 results in changes to the effective refractive index of the semiconductor layer 202 and the optical spacer structure 208. In some implementations, the half-pitch between adjacent gratings 404 (dimension D3) may be selected to be approximately equal to or less than the wavelength of incident light that is to be sensed by the photodetector structure 102.

If different photodetector structures 102 in the semiconductor device 100 are configured to sense incident light of different wavelengths, the z-direction heights of the gratings 404 for the photodetector structures 102 may be different. Thus, the semiconductor device 100 may include a plurality of photodetector structures 102 that include grating structures 402, and the gratings 404 of the grating structures 402 of the photodetector structures 102 may have different z-direction heights. Additionally and/or alternatively, the gratings 404 of the grating structures 402 of the photodetector structures 102 may have different lateral widths, and/or the recesses 406 of the grating structures 402 of the photodetector structures 102 may have different lateral widths (e.g., to achieve different effective refractive indexes for the grating structures 402 of the photodetector structures 102).

For example, a first photodetector structure 102 of the semiconductor device 100 may be configured to sense a first wavelength of incident light, and a second photodetector structure 102 of the semiconductor device 100 may be configured to sense a second wavelength of incident light that is different than the first wavelength. Accordingly, the z-direction heights of the gratings 404 of the respective grating structures 402 of the first and second photodetector structures 102 may be different z-direction thicknesses. As an example, if the first wavelength is less than the second wavelength, the z-direction height of the gratings 404 of the grating structure 402 of the first photodetector structure 102 may be greater than the z-direction height of the gratings 404 of the grating structure 402 of the second photodetector structure 102.

As another example, a first photodetector structure 102 of the semiconductor device 100 may be configured to sense a first wavelength range of incident light, and a second photodetector structure 102 of the semiconductor device 100 may be configured to sense a second wavelength range of incident light that is different than the first wavelength range. Accordingly, the z-direction heights of the gratings 404 of the respective grating structures 402 of the first and second photodetector structures 102 may be different z-direction thicknesses.

As further shown in FIG. 4, the optical spacer structure 208 may be included above the photon absorption region 204. As indicated above, portions of the optical spacer structure 208 extend into the recesses 406 of the grating structure 402 between adjacent gratings 404 of the grating structure 402. A micro-lens structure 210 may be included above the optical spacer structure 208.

As indicated above, FIG. 4 is provided as an example. Other examples may differ from what is described with regard to FIG. 4.

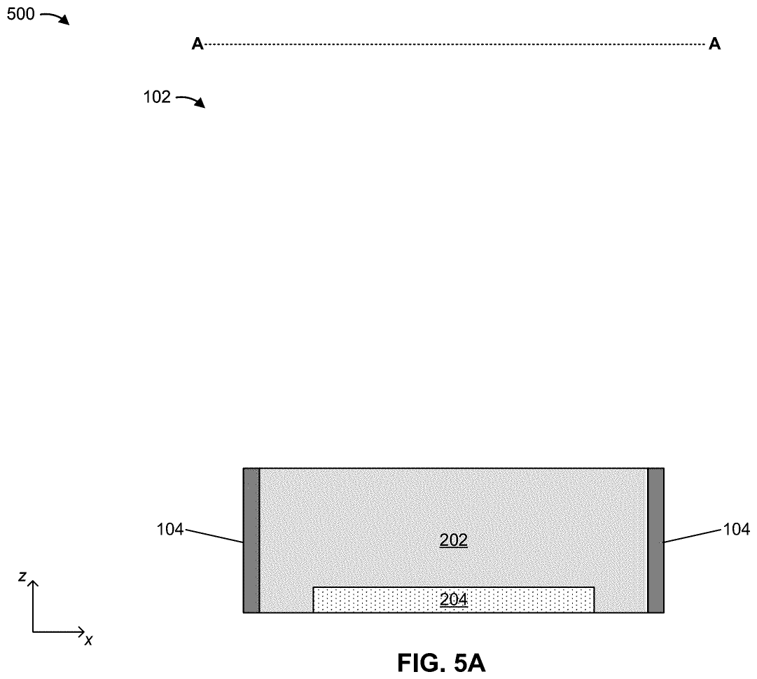

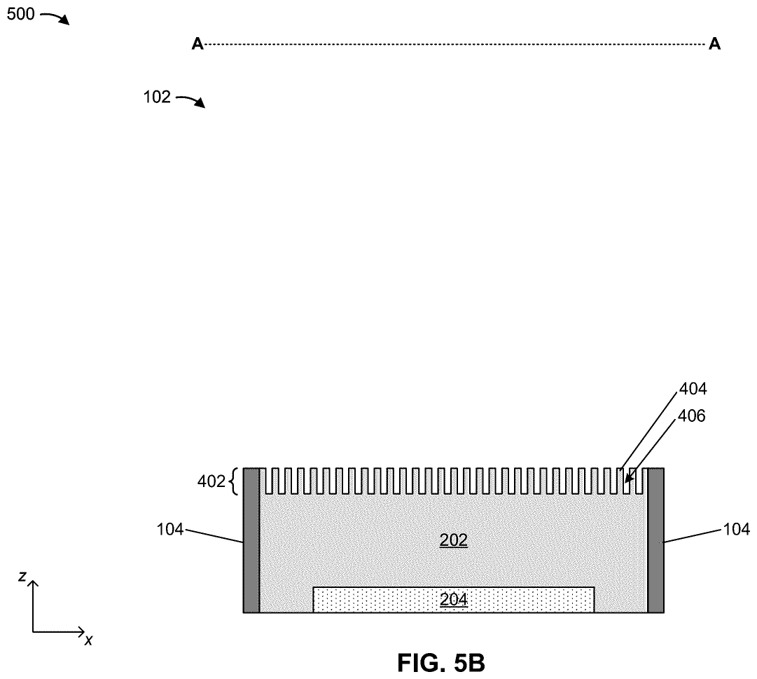

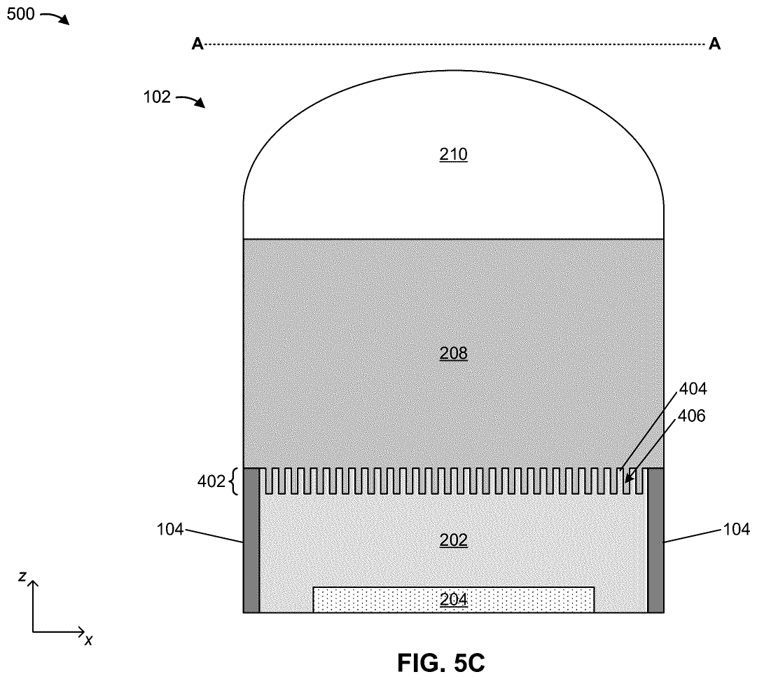

FIGS. 5A-5C are diagrams of an example implementation 500 of forming a semiconductor device 100 described herein. In particular, the example implementation 500 may include an example of forming one or more photodetector structures 102 of the semiconductor device 100. In some implementations, one or more of the semiconductor processing operations described in connection with FIGS. 5A-5C may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 5A, one or more of the semiconductor processing operations illustrated and described in connection with FIGS. 3A-3D may be performed to form the isolation structure 104 and the photon absorption region 204 of the photodetector structure 102 in and/or on the semiconductor layer 202.

As shown in FIG. 5B, the grating structure 402 of the photodetector structure 102 may be formed in the surface (e.g., the back side surface) of the semiconductor layer 202. For example, the surface of the semiconductor layer 202 above the photon absorption region 204 may be etched to form the recesses 406 in the surface of the semiconductor layer 202, where the gratings 404 of the grating structure 402 define the recesses 406.

In some implementations, a pattern in a photoresist layer is used to etch the semiconductor layer 202 to form the recesses 406 of the grating structure 402. In these implementations, a deposition tool may be used to form the photoresist layer on the semiconductor layer 202 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 202 based on the pattern to form the recesses 406. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 202 based on a pattern.

The recesses 406 may be formed to a z-direction depth such that the gratings 404 have a z-direction height (e.g., dimension D3) that is based on the wavelength (or wavelength range) of incident light that is to be sensed by the photodetector structure 102, and/or that is based on the effective refractive index of the semiconductor layer 202 and the optical spacer structure 208 that is to be formed in the recesses 406.

In some implementations, a plurality of photodetector structures 102 are formed in and/or on the semiconductor layer 202. For example, a first photodetector structure 102 and a second photodetector structure 102 may be formed in and/or on the semiconductor layer 202. The first photodetector structure 102 and the second photodetector structure 102 may be configured to sense different wavelengths (or different wavelength ranges) of incident light. For example, the first photodetector structure 102 may be configured to sense a near infrared wavelength range of incident light, and the second photodetector structure 102 may be configured to sense a visible light wavelength range of incident light. Accordingly, a first grating structure 402 having gratings 404 that have a first z-direction height may be formed for the first photodetector structures 102, and a second grating structure 402 having gratings 404 that have a second z-direction height may be formed for the second photodetector structures 102, where the first z-direction height and the second z-direction height are different z-direction heights.

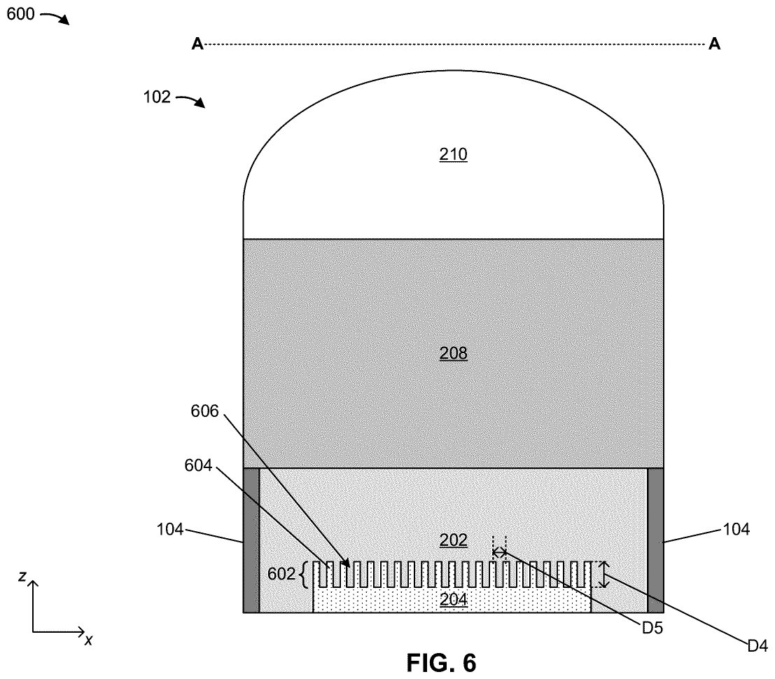

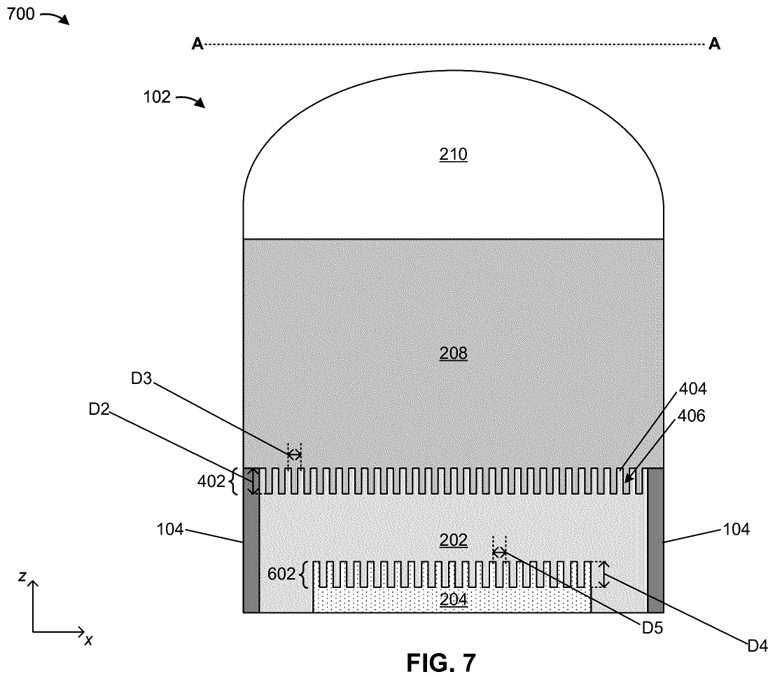

In some implementations, a first photodetector structure 102 may be formed to include a grating structure 402 in the surface (e.g., the back side surface) of the semiconductor layer 202 above the photon absorption region 204 of the first photodetector structure 102, a second photodetector structure 102 may be formed to include a grating structure in the photon absorption region 204 of the second photodetector structure 102 (as illustrated in an example in FIG. 6), and/or a third photodetector structure 102 may be formed to include a grating structure 402 in the surface of the semiconductor layer 202 above the photon absorption region 204 of the third photodetector structure 102 and another grating structure in the photon absorption region 204 of the third photodetector structure 102 (as illustrated in an example in FIG. 7).

As shown in FIG. 5C, the optical spacer structure 208 of the photodetector structure 102 may be formed above and/or on the grating structure 402. Portions of the optical spacer structure 208 may be deposited in the recesses 406 between the gratings 404 of the grating structure 402. Moreover, a micro-lens structure 210 of the photodetector structure 102 may be formed above and/or on the optical spacer structure 208.

As indicated above, FIGS. 5A-5C are provided as an example. Other examples may differ from what is described with regard to FIGS. 5A-5C.

FIG. 6 is a diagram of an example implementation 600 of a photodetector structure 102 that may be included in the semiconductor device 100 described herein. As shown in FIG. 6, the example implementation 600 of the photodetector structure 102 includes a similar combination and/or arrangement of layers and/or structures as the example implementation 400 of the photodetector structure 102 in FIG. 4. However, in the example implementation 600 of the photodetector structure 102, the grating structure 402 in the surface (e.g., the back side surface) of the semiconductor layer 202 is omitted. Instead, a grating structure 602 is included in the surface of the photon absorption region 204.

The grating structure 602 may be formed of a different material (e.g., germanium (Ge), silicon germanium (SiGe)) than the material of the grating structure 402 (e.g., silicon (Si), doped silicon). Moreover, the z-direction height (indicated in FIG. 6 as dimension D4) of gratings 604 of the grating structure 602 may be selected based on the effective refractive index of the semiconductor layer 202 (e.g., that extends into recesses 606 between the gratings 604) and the photon absorption region 204, additionally and/or alternatively to the wavelength of incident light that is to be sensed by the photodetector structure 102. The effective refractive index of the semiconductor layer 202 and the photon absorption region 204 at the grating structure 602 may be based on the lateral (e.g., x-direction) width of the gratings 604, based on the lateral (e.g., x-direction) width of the recesses 606, and/or based on the half-pitch (indicated in FIG. 6 as dimension D5) between adjacent gratings 604, among other examples.

As indicated above, FIG. 6 is provided as an example. Other examples may differ from what is described with regard to FIG. 6.

FIG. 7 is a diagram of an example implementation 700 of a photodetector structure 102 that may be included in the semiconductor device 100 described herein. As shown in FIG. 7, the example implementation 700 of the photodetector structure 102 includes a similar combination and/or arrangement of layers and/or structures as the example implementation 400 of the photodetector structure 102 in FIG. 4. However, in the example implementation 700 of the photodetector structure 102, a grating structure 602 is included in the surface of the photon absorption region 204 in addition to the grating structure 402 in the surface (e.g., the back side surface) of the semiconductor layer 202.

In some implementations, the gratings 404 of the grating structure 402 and the gratings 604 of the grating structure 602 may be formed of different materials. For example, the gratings 404 of the grating structure 402 may be formed in the semiconductor layer 202 and may include the material of the semiconductor layer 202 (e.g., silicon (Si), doped silicon), and the gratings 604 of the grating structure 602 may be formed in the photon absorption region 204 and may include the material of the photon absorption region 204 (e.g., germanium (Ge), silicon germanium (SiGe)). alternatively, the gratings 404 of the grating structure 402 and the gratings 604 of the grating structure 602 may be formed of the same material.

In some implementations, the gratings 404 of the grating structure 402 and the gratings 604 of the grating structure 602 may have different z-direction heights. For example, the gratings 404 of the grating structure 402 may have a z-direction height (dimension D2) that is based on the effective refractive index of the semiconductor layer 202 and the optical spacer structure 208 at the grating structure 402, and the gratings 604 of the grating structure 602 may have a z-direction height (dimension D4) that is based on the effective refractive index of the semiconductor layer 202 and the photon absorption region 204 at the grating structure 602.

In some implementations, the gratings 404 of the grating structure 402 and the gratings 604 of the grating structure 602 may have approximately a same half-pitch (dimension D3≈D5). In some implementations, the gratings 404 of the grating structure 402 and the gratings 604 of the grating structure 602 may have different half-pitches.

As indicated above, FIG. 7 is provided as an example. Other examples may differ from what is described with regard to FIG. 7.

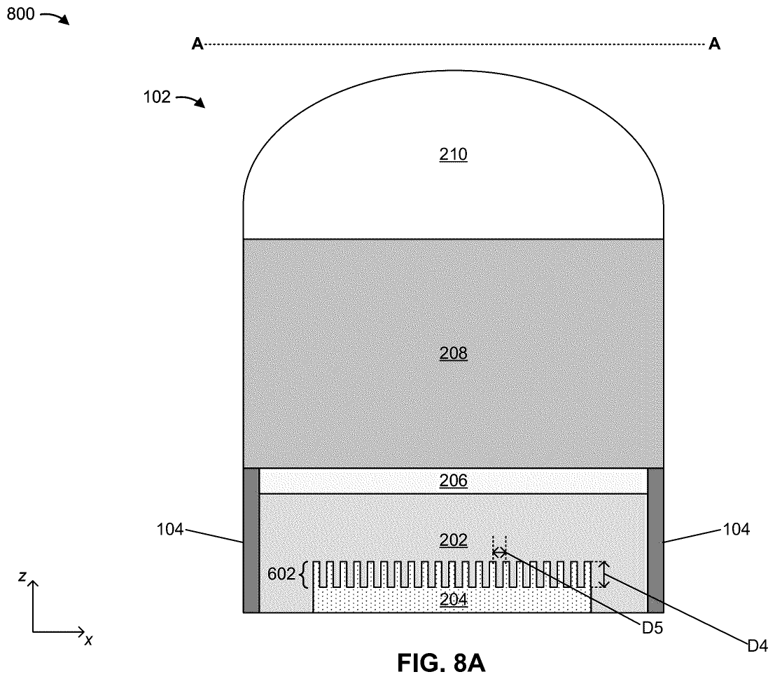

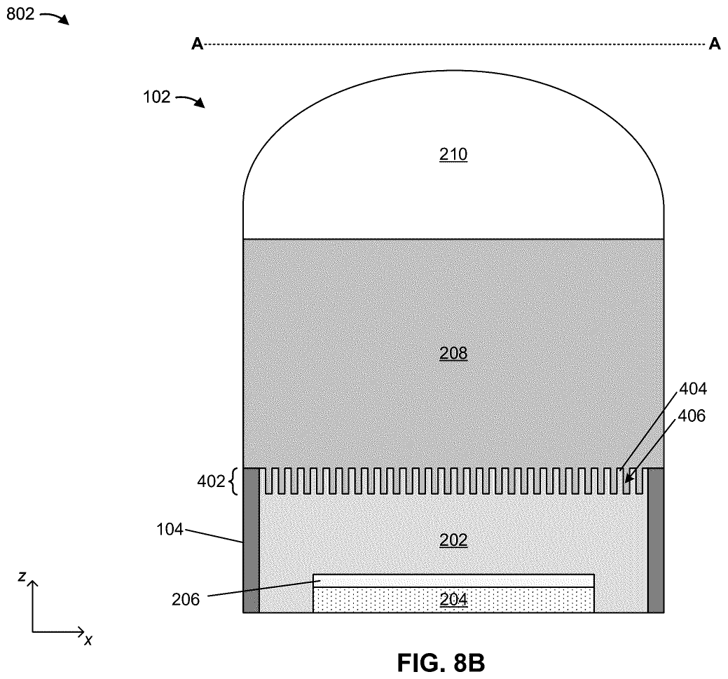

FIGS. 8A and 8B are diagrams of example implementations of photodetector structures 102 that may be included in the semiconductor device 100 described herein. In the example implementations illustrated in FIGS. 8A and 8B, a photodetector structure 102 includes a combination of an anti-reflection film and a grating structure that function as anti-reflection structures for the photodetector structure 102. In an example implementation 800 in FIG. 8A, a photodetector structure 102 includes an anti-reflective film 206 on the surface (e.g., the back side surface) of the semiconductor layer 202 and a grating structure 602 on the photon absorption region 204. The various combinations of anti-reflection films and grating structures increase transmittance and/or reduce reflectance of incident light through destructive interference of reflected waves of incident light. In an example implementation 802 in FIG. 8B, a photodetector structure 102 includes an anti-reflective film 206 on the photon absorption region 204 and a grating structure 402 in the surface (e.g., the back side surface) of the semiconductor layer 202. In this way, the various combinations of anti-reflection films and grating structures in the example implementations in FIGS. 8A and 8B increase the quantum efficiency of the photodetector structures 102. Moreover, the various combinations of anti-reflection films and grating structures in the example implementations in FIGS. 8A and 8B provide increased flexibility for reducing reflections for the photodetector structures 102 in that the various combinations of anti-reflection films and grating structures provide more options for tuning the performance of the photodetector structures 102.

As indicated above, FIGS. 8A and 8B are provided as examples. Other examples may differ from what is described with regard to FIGS. 8A and 8B.

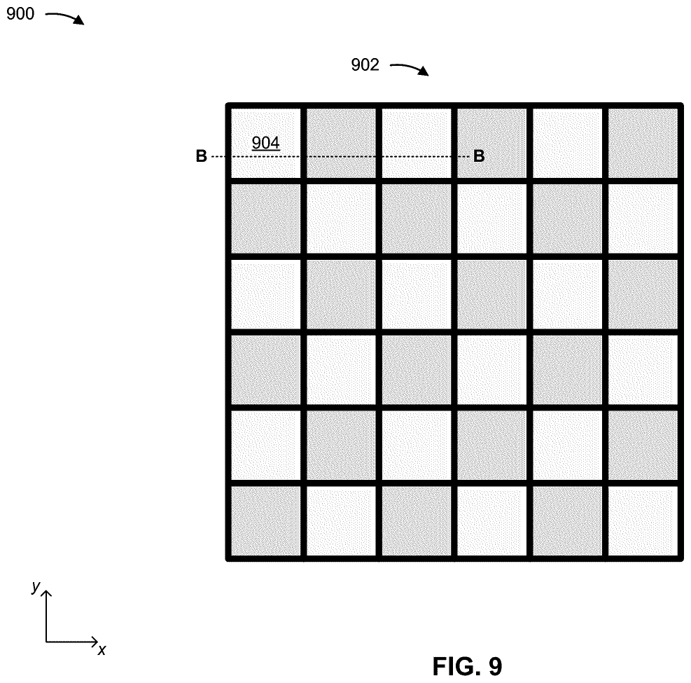

FIG. 9 is a diagram of an example of a portion of a semiconductor device 900 described herein. The semiconductor device 900 may include an image sensor device, such as a complementary metal-oxide-semiconductor (CMOS) image sensor device (CIS) that includes a pixel sensor array 902.

FIG. 9 illustrates a top view of the pixel sensor array 902. As shown in FIG. 9, the pixel sensor array 902 includes a plurality of pixel sensors 904. The pixel sensors 904 may be arranged in a grid, as shown in the example in FIG. 9. In some implementations, the pixel sensors 904 are square-shaped, as shown in the example in FIG. 9. In some implementations, the pixel sensors 904 include other shapes such as rectangle shapes, circle shapes, octagon shapes, diamond shapes, and/or other shapes. However, other quantities, arrangements, and/or shapes of pixel sensors 904 for the pixel sensor array 902 of the semiconductor device 900 are within the scope of the present disclosure.

The pixel sensor array 902 may include various types of pixel sensors 904. For example, one or more pixel sensors 904 in the pixel sensor array 902 may be white pixel sensors (or “clear” pixel sensors). A white pixel sensor (or a “clear” pixel sensor) is a non-discriminating or non-filtering pixel sensor that is configured to sense incident light across the entire visible light spectrum. A white pixel sensor may be used for the general detection of objects in the field of view of the pixel sensor array 902, such as trucks, pedestrians, obstacles, and/or backgrounds, among other examples.

As another example, one or more pixel sensors 904 in the pixel sensor array 902 may be visible light (e.g., color) pixel sensors. A visible light pixel sensor is a pixel sensor that senses a portion of the visible light spectrum of incident light. In particular, a visible light pixel sensor may be configured to sense a particular wavelength range of incident light associated with a particular color of visible light. For example, a visible light pixel sensor may be configured to sense a wavelength range associated with a red component of incident light, and may therefore be referred to as a red pixel sensor. As another example, a visible light pixel sensor may be configured to sense a wavelength range associated with a blue component of incident light, and may therefore be referred to as a blue pixel sensor. As another example, a visible light pixel sensor may be configured to sense a wavelength range associated with a green component of incident light, and may therefore be referred to as a green pixel sensor. The visible light pixel sensors may be used for detecting particular types of objects in the field of view of the pixel sensor array 902, such as traffic lights, road signs, buildings, animals, and/or vehicles, among other examples.

As another example, one or more pixel sensors 904 in the pixel sensor array 902 may be near infrared (NIR) light pixel sensors. An NIR light pixel sensor is a pixel sensor that senses at least a portion of the NIR light spectrum of incident light. The NIR light pixel sensors may be used for low-light imaging, night vision, and/or other low-light applications.

As indicated above, FIG. 9 is provided as an example. Other examples may differ from what is described with regard to FIG. 9.

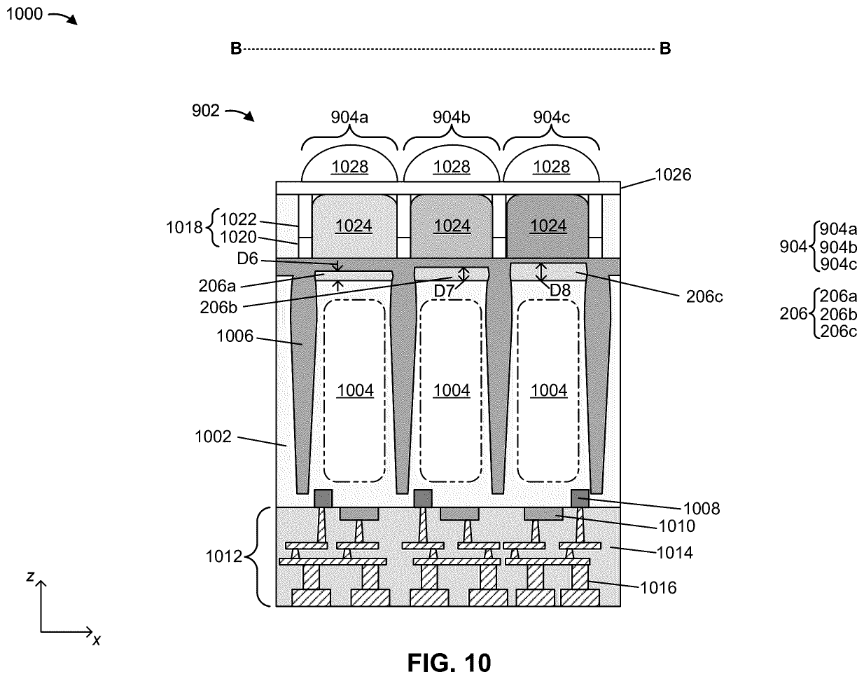

FIG. 10 is a diagram of example implementation 1000 of a portion of the pixel sensor array 902 of the semiconductor device 900 described herein. FIG. 10 illustrates a cross-section view of the portion of the pixel sensor array 902 along the line B-B in FIG. 9.

As shown in FIG. 10, the portion of the pixel sensor array 902 includes a plurality of pixel sensors 904, including a pixel sensor 904a, a pixel sensor 904b, and/or a pixel sensor 904c, among other examples. The pixel sensors 904a-904c may be formed in and/or on a semiconductor layer 1002 of the semiconductor device 900. The semiconductor layer 1002 may include a semiconductor substrate, a semiconductor die substrate, a semiconductor wafer, a semiconductor layer of an SOI substrate, and/or another type of semiconductor layer.

Each of the pixel sensors 904a-904c may include a photodiode 1004. The photodiodes 1004 may include regions of the semiconductor layer 1002 that are doped with various types of ions to form a p-n junction or a PIN junction (e.g., a junction between a p-type portion, an intrinsic (or undoped) type portion, and an n-type portion). For example, the semiconductor layer 1002 may be doped with an n-type dopant to form one or more n-type regions of a photodiode 1004, and the semiconductor layer 1002 may be doped with a p-type dopant to form a p-type region of the photodiode 1004. A photodiode 1004 may be configured to absorb photons of incident light that enter the semiconductor layer 1002. The absorption of photons causes the photodiode 1004 to accumulate a charge (referred to as a photocurrent) due to the photoelectric effect. Photons may bombard the photodiode 1004, which causes emission of electrons in the photodiode 1004.

An isolation structure 1006 may be included around the photodiodes 1004 of the pixel sensors 904 of the pixel sensor array 902. The isolation structure 1006 may be a DTI structure that includes a plurality of interconnected elongated segments that extend downward into the semiconductor layer 1002. The elongated segments may extend into the semiconductor layer 1002 from a back side surface of the semiconductor layer 1002 opposing the front side surface. The pixel sensor array 902 may be referred to as a back side illuminated (BSI) pixel sensor array in that photons enter the photodiodes 1004 from the back side surface of the semiconductor layer 1002. Thus, the isolation structure 1006 may be referred to as a back side DTI (BDTI) structure. Alternatively, the isolation structure 1006 may include a front side DTI (FDTI) structure that extends into the semiconductor layer 1002 from the front surface of the semiconductor layer 1002.

The isolation structure 1006 may include one or more layers. The one or more layers may include a liner, a fill layer, an insert, and/or another layer, among other examples. A portion of the isolation structure 1006 may extend along the back side surface of the semiconductor layer 1002 over the photodiodes 1004. Alternatively, the isolation structure 1006 may be omitted from the back side surface of the semiconductor layer 1002.

The isolation structure 1006 may be included to confine incident light around a photodiode 1004 of an associated pixel sensor 904 to increase the quantum efficiency of the pixel sensor and/or to reduce optical crosstalk between adjacent pixel sensors 904 in the pixel sensor array 902. In some implementations, the isolation structure 1006 includes one or more dielectric materials, such as a silicon oxide (SiOₓ), a silicon nitride (SiₓN_{y}), a silicon carbide (SiCₓ), a silicon carbon nitride (SiCN), silicon oxynitride (SiON), an aluminum oxide (AlₓO_{y} such as Al₂O₃), a tantalum oxide (TaₓO_{y} such as Ta₂O₅), a hafnium oxide (HfOₓ such as HfO₂) and/or another high-k dielectric material.

The photocurrent generated by a photodiode 1004 of a pixel sensor 904 may be transferred and/or stored in an associated floating diffusion (FD) node 1008 in the semiconductor layer 1002. An FD node 1008 may include a doped portion (e.g., an n-doped portion, a p-doped portion) of the semiconductor layer 1002 that is configured to accumulate and store a photocurrent.

A pixel sensor 904 may also include a transfer gate 1010 on the front side of the semiconductor layer 1002. The transfer gate 1010 of the pixel sensor 904 may be configured to transfer the photocurrent generated by a photodiode 1004 to an FD node 1008. A transfer gate 1010 may be implemented by a field effect transistor (FET), such as a planar FET, a finFET, a nanostructure FET (e.g., a gate all around (GAA) FET, a nanowire FET, a nanosheet FET, a multi-bridge channel FET, a nanoribbon FET), and/or another type of FET.

An interconnect layer 1012 (e.g., a back end of line (BEOL) region or backend region) may be included on the front side of the semiconductor layer 1002. The interconnect layer 1012 may include one or more dielectric layers 1014 and one or more metallization layers 1016 included in the one or more dielectric layers 1014. One or more of the metallization layers 1016 may be electrically connected with portions of the pixel sensor array 902, including the FD nodes 1008 and/or the transfer gates 1010. The one or more dielectric layers 1014 may include a silicon oxide (SiOₓ), a silicon nitride (SiₓN_{y}), a silicon carbide (SiCₓ), or a mixture thereof, such as a silicon carbon nitride (SiCN), or a silicon oxynitride (SiON), among other examples. The one or more metallization layers 1016 may include contacts, trenches, vias, interconnects, columns, pillars, single damascene structures, and/or dual damascene structures, among other examples. The one or more metallization layers 1016 may include tungsten (W), cobalt (Co), titanium (Ti), copper (Cu), gold (Au), silver (Ag), molybdenum (Mo), ruthenium (Ru), a metal alloy, and/or another type of electrically conductive material, among other examples.

The isolation grid 1018 may include an isolation structure (e.g., a grid structure or grid isolation structure) above the isolation structure 1006. The isolation grid 1018 may include a plurality of interconnected structures formed from one or more layers that are etched to form the interconnected structures. In a top view of the isolation grid 1018, the isolation grid 1018 has a grid-shaped configuration similar to the isolation structure 1006. The isolation grid 1018 may be configured to provide increased optical crosstalk reduction for the pixel sensor array 902, in combination with the isolation structure 1006.

The isolation grid 1018 may include an oxide grid, a dielectric grid, a color filter in a box (CIAB) grid, and/or a composite metal grid (CMG), among other examples. In some implementations, the isolation grid 1018 includes a metal layer 1020 and a dielectric layer 1022 over and/or on the metal layer 1020. The metal layer 1020 may include tungsten (W), cobalt (Co), and/or another type of metal or metal-containing material. The dielectric layer 1022 may include an organic material, an oxide, a nitride, and/or another type of dielectric material such as a silicon oxide (SiOₓ) (e.g., silicon dioxide (SiO₂)), a hafnium oxide (HfOₓ), a hafnium silicon oxide (HfSiOₓ), an aluminum oxide (AlₓO_{y}), a silicon nitride (SiₓN_{y}), a zirconium oxide (ZrOₓ), a magnesium oxide (MgOₓ), a yttrium oxide (YₓO_{y}), a tantalum oxide (TaₓO_{y}), a titanium oxide (TiOₓ), a lanthanum oxide (LaₓO_{y}), a barium oxide (BaOₓ), a silicon carbide (SiC), a lanthanum aluminum oxide (LaAlOₓ), a strontium oxide (SrO), a zirconium silicon oxide (ZrSiOₓ), and/or a calcium oxide (CaO), among other examples.

A color filter 1024 may be included in the areas between the columns of the isolation grid 1018. In particular, the color filter 1024 may be included in between columns of the isolation grid 1018 over the photodiodes 1004 of the pixel sensors 904. Each of the pixel sensors 904 may include a respective color filter 1024. For example, a color filter 1024 may be included above the photodiode 1004 of the pixel sensor 904a, a color filter 1024 may be included above the photodiode 1004 of the pixel sensor 904b, a color filter 1024 may be included above the photodiode 1004 of the pixel sensor 904c, and so on.

The color filter 1024 for a pixel sensor 904 may include a layer, a doped region, a structure, and/or another element that is configured to filter incident light to allow a particular wavelength of the incident light to pass to the photodiode 1004 of the pixel sensor 904. For example, the color filter 1024 for the pixel sensor 904a may include a material composition that is transmissive for a particular wavelength (or wavelength range) of the incident light associated with blue light. As another example, the color filter 1024 for the pixel sensor 904b may include a material composition that is transmissive for a particular wavelength (or wavelength range) of the incident light associated with green visible light. As another example, the color filter 1024 for the pixel sensor 904c may include a material composition that is transmissive for a particular wavelength (or wavelength range) of the incident light associated with red visible light.

As further shown in FIG. 10, one or more pixel sensors 904 in the pixel sensor array 902 may include an anti-reflection film 206. The anti-reflection film 206 of a pixel sensor 904 may be positioned above and/or over the photodiode 1004 of the pixel sensor 904 such that photons of incident light pass through the anti-reflection film 206 toward the photodiode 1004. The anti-reflection film 206 may reduce reflection of incident light away from the photodiode 1004 of the pixel sensor 904 so that a high quantum efficiency can be achieved for the pixel sensor 904. In some implementations, the anti-reflection film 206 is located vertically between the semiconductor layer 1002 and the portion of the isolation structure 1006 extending over the photodiode 1004 of the pixel sensor 904.

As further shown in FIG. 10, two or more pixel sensors 904 may include separate anti-reflection films 206. For example, the pixel sensor 904a may include an anti-reflection film 206a above the photodiode 1004 of the pixel sensor 904a, the pixel sensor 904b may include an anti-reflection film 206b above the photodiode 1004 of the pixel sensor 904b, the pixel sensor 904c may include an anti-reflection film 206c above the photodiode 1004 of the pixel sensor 904c, and so on. As indicated above, the pixel sensors 904a-904c may include color filters 1024 that filter different wavelengths (or different wavelength ranges) of incident light. Accordingly, the anti-reflection films 206a-206c may have different z-direction thicknesses so that destructive interference reduces, minimizes, and/or prevents reflection of incident light for each of the different wavelengths (or different wavelength ranges) of incident light for the pixel sensors 904a-904c.

As an example of the above, the pixel sensor 904a may be a blue pixel sensor, the pixel sensor 904b may be a green pixel sensor, and the pixel sensor 904c may be a red pixel sensor. Thus, the photodiode 1004 of the pixel sensor 904a is configured to absorb incident light having the shortest wavelength of the pixel sensors 904a-904c, the photodiode 1004 of the pixel sensor 904c is configured to absorb incident light having the longest wavelength of the pixel sensors 904a-904c, and the photodiode 1004 of the pixel sensor 904b is configured to absorb incident light having a wavelength that is within a range of the wavelengths sensed by the pixel sensors 904a and 904c. Accordingly, the z-direction thickness of the anti-reflection film 206a (indicated in FIG. 10 as dimension D6) may be less than the z-direction thickness of the anti-reflection film 206b (indicated in FIG. 10 as dimension D7) and the z-direction thickness of the anti-reflection film 206c (indicated in FIG. 10 as dimension D8). The z-direction thickness of the anti-reflection film 206b (dimension D7) may be greater than the z-direction thickness of the anti-reflection film 206a (dimension D6) and less than the z-direction thickness of the anti-reflection film 206c (dimension D8). The z-direction thickness of the anti-reflection film 206c (dimension D8) may be greater than the z-direction thickness of the anti-reflection film 206a (dimension D6) and the z-direction thickness of the anti-reflection film 206b (dimension D7).

Additionally and/or alternatively, the anti-reflection films 206a-206c may include different materials to achieve different effective refractive indexes for the pixel sensors 904a-904c. For example, the anti-reflection film 206a of the pixel sensor 904a may include tantalum oxide (TaₓO_{y} such as Ta₂O₅), the anti-reflection film 206b of the pixel sensor 904b may include silicon oxide (SiOₓ such as SiO₂), and/or the anti-reflection film 206c of the pixel sensor 904c may include silicon oxynitride (SiON). However, other combinations of materials are within the scope of the present disclosure.

A buffer layer 1026 may be included over the color filters 1024. The buffer layer 1026 may include one or more dielectric materials, such as a silicon oxide (SiOₓ), a silicon nitride (SiₓN_{y}), a silicon carbide (SiCₓ), a silicon carbon nitride (SiCN), and/or a silicon oxynitride (SiON), among other examples.

Micro-lens structures 1028 may be included above the buffer layer 1026. In some implementations, each of the pixel sensors 904 includes a micro-lens structure 1028. For example, the pixel sensor 904a may include a micro-lens structure 1028 that spans across the entire color filter 1024 of the pixel sensor 904a, the pixel sensor 904b may include a micro-lens structure 1028 that spans across the entire color filter 1024 of the pixel sensor 904b, the pixel sensor 904c may include a micro-lens structure 1028 that spans across the entire color filter 1024 of the pixel sensor 904c, and so on. The micro-lens structures 1028 of the pixel sensors 904 may be formed to focus incident light toward the photodiodes 1004 of the pixel sensors 904.

As indicated above, FIG. 10 is provided as an example. Other examples may differ from what is described with regard to FIG. 10.

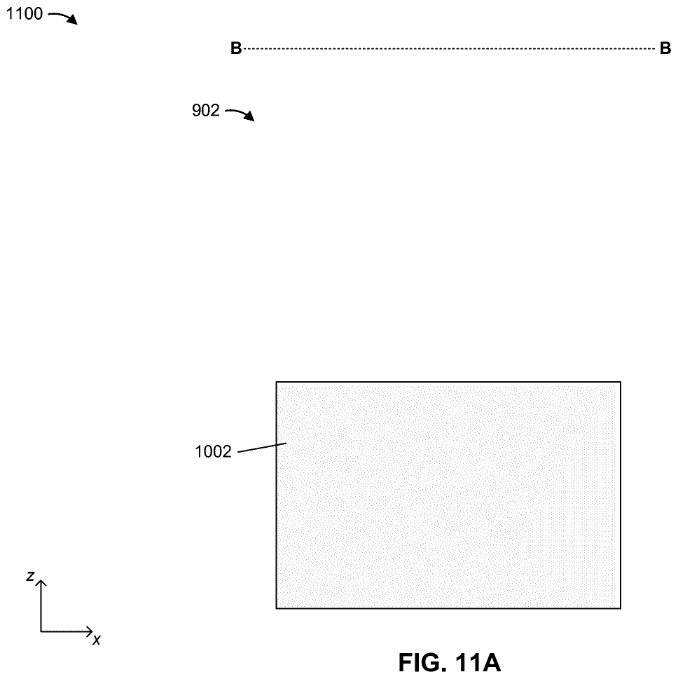

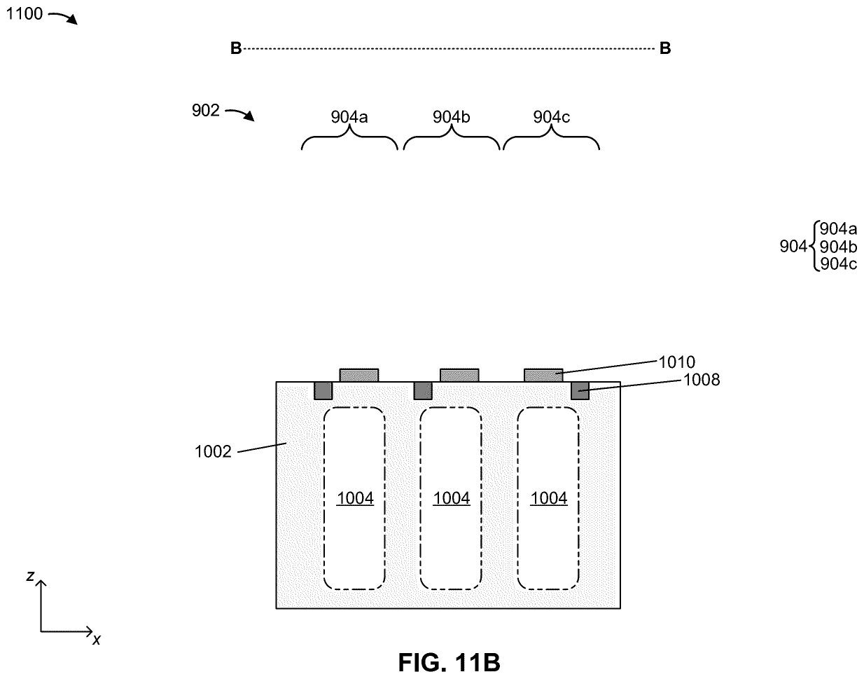

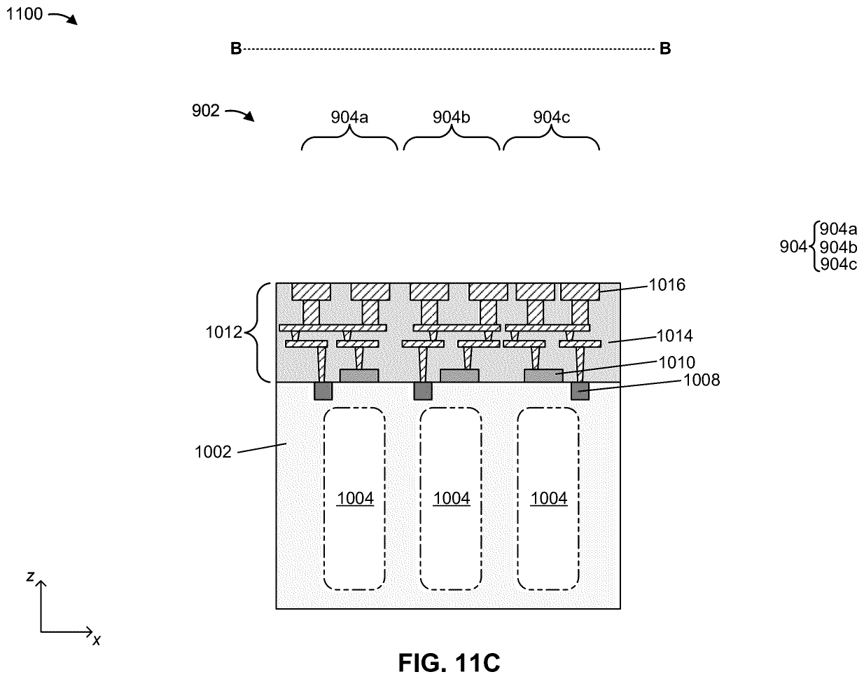

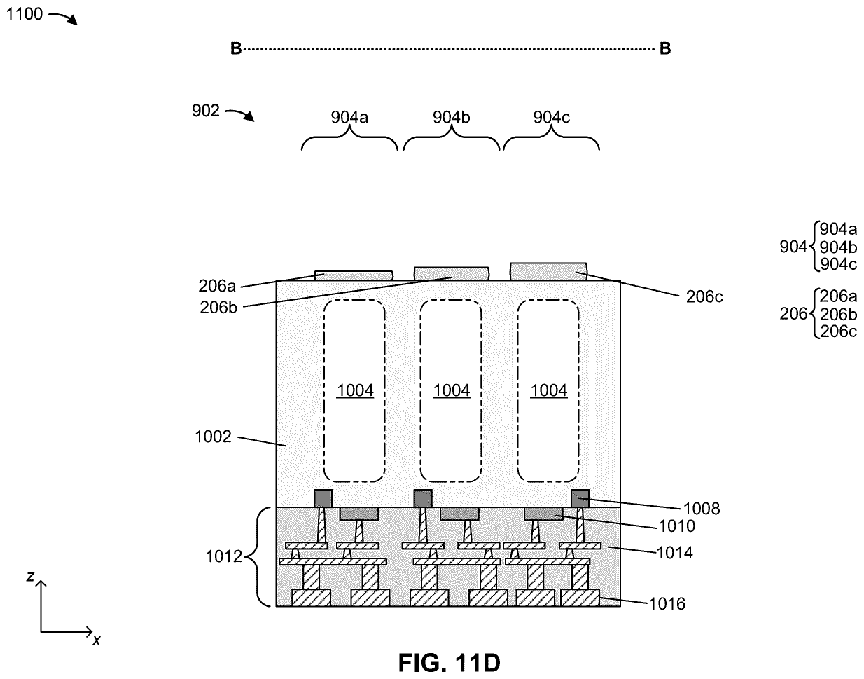

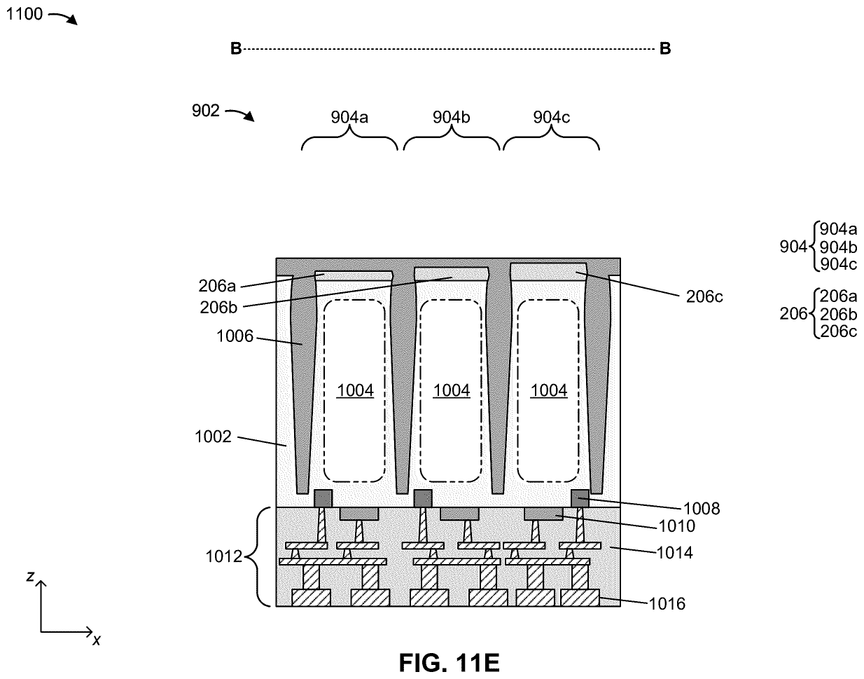

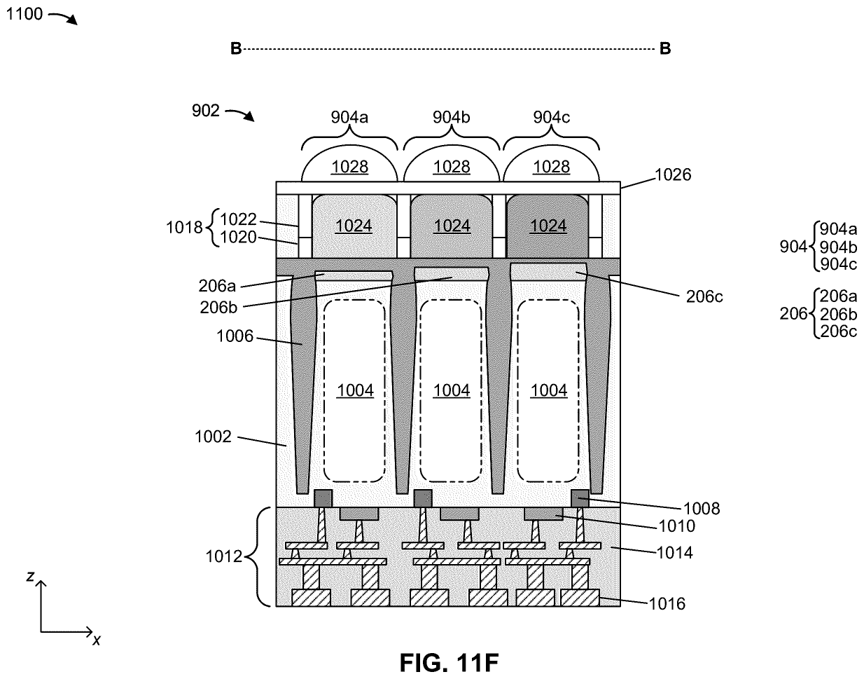

FIGS. 11A-11F are diagrams of an example implementation 1100 of forming a semiconductor device 900 described herein. In some implementations, one or more of the semiconductor processing operations described in connection with FIGS. 11A-11F may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 11A, one or more of the semiconductor processing operations in the example implementation 1100 may be performed in connection with the semiconductor layer 1002. The semiconductor layer 1002 may be provided as a semiconductor wafer or another type of semiconductor work piece.

As shown in FIG. 11B, a plurality of regions of the semiconductor layer 1002 may be doped to form photodiodes 1004 of the pixel sensors 904 of the pixel sensor array 902 of the semiconductor device 900. For example, a photodiode 1004 may be formed in the semiconductor layer 1002 for the pixel sensor 904a, a photodiode 1004 may be formed in the semiconductor layer 1002 for the pixel sensor 904b, a photodiode 1004 may be formed in the semiconductor layer 1002 for the pixel sensor 904c, and so on. An ion implantation tool may be used to dope the semiconductor layer 1002 to form one or more n-type regions and/or one or more p-type regions of the photodiodes 1004. The ion implantation tool may be used to implant p ions in the semiconductor layer 1002 to form the p-type region(s) and/or may implant n ions in the semiconductor layer 1002 to form the n-type region(s).

As further shown in FIG. 11B, one or more regions of the semiconductor layer 1002 may be doped to form the FD nodes 1008 of the pixel sensors 904. In some implementations, an ion implantation tool may be used to dope by implanting n′ ions in the semiconductor layer 1002 to form the FD nodes 1008.

As further shown in FIG. 11B, transfer gates 1010 of the pixel sensors 904 may be formed over the front side surface of the semiconductor layer 1002. In some implementations, a gate dielectric layer may be formed on the front side surface of the semiconductor layer 1002, and the transfer gates 1010 may be formed over and/or on the gate dielectric layer. In some implementations, a deposition tool is used to deposit the transfer gates 1010. In some implementations, the transfer gates 1010 may include polysilicon that is doped with one or more types of dopants. In some implementations, the transfer gates 1010 may include high-k dielectric and metal materials (e.g., metal gates or MGs).

As shown in FIG. 11C, an interconnect layer 1012 may be formed above the front side surface of the semiconductor layer 1002. Forming the interconnect layer 1012 may include forming one or more dielectric layers 1014 and forming one or more metallization layers 1016 in the one or more dielectric layers 1014. For example, a first dielectric layer 1014 may be formed and patterned to form recesses in the first dielectric layer 1014, and a first metallization layer 1016 may be formed in the recesses in the first dielectric layer 1014. Subsequent layers of the interconnect layer 1012 may be formed in a similar manner.

A deposition tool may be used to deposit the dielectric layer(s) 1014 using a PVD technique, an ALD technique, a CVD technique, an oxidation technique, and/or another type of deposition technique. In some implementations, a planarization tool may be used to planarize the dielectric layer(s) 1014 after the dielectric layer(s) 1014 are deposited.

In some implementations, a pattern in a photoresist layer is used to etch a dielectric layer 1014 to form the recesses in the dielectric layer 1014 for the metallization layers 1016. In these implementations, a deposition tool may be used to form the photoresist layer on a dielectric layer 1014. An exposure tool may be used to expose the photoresist layer to a radiation source to pattern the photoresist layer. A developer tool may be used to develop and remove portions of the photoresist layer to expose the pattern. An etch tool may be used to etch the dielectric layer 1014 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 1014 based on a pattern.

A deposition tool may be used to deposit the metallization layers 1016 using a PVD technique, an ALD technique, a CVD technique, an electroplating (e.g., an electro-chemical plating) technique, and/or another type of deposition technique. In some implementations, a planarization tool may be used to planarize the metallization layers 1016 after the metallization layers 1016 are deposited. In some implementations, a seed layer is first deposited, and a metallization layer 1016 is formed on the seed layer. In some implementations, one or more liners (e.g., a barrier layer, an adhesion layer) is first deposited, and a metallization layer 1016 is formed on the one or more liners.

As shown in FIG. 11D, back side processing may be performed on the back side of surface of the semiconductor layer 1002. The anti-reflection films 206 may be formed over the photodiodes 1004 of the pixel sensors 904. For example, an anti-reflection film 206a may be formed over the photodiode 1004 of the pixel sensor 904a, an anti-reflection film 206b may be formed over the photodiode 1004 of the pixel sensor 904b, an anti-reflection film 206c may be formed over the photodiode 1004 of the pixel sensor 904c, and so on. In some implementations, the anti-reflection films 206a-206c are formed of the same material and from the same layer. The layer may be deposited and etched to define the anti-reflection films 206a-206c. In some implementations, the anti-reflection films 206a-206c are formed of different materials and are deposited in separate deposition operations.

In some implementations, the anti-reflection films 206a-206c are formed to different z-direction thicknesses based on the wavelengths of incident light that are to be sensed by the pixel sensors 904a-904c. To form the anti-reflection films 206a-206c to different z-direction thicknesses, a first patterned masking layer may be formed over the back side of the semiconductor layer 1002, and the anti-reflection film 206a may be formed to a first z-direction thickness (dimension D6). A second patterned masking layer may be formed over the back side of the semiconductor layer 1002, and the anti-reflection film 206b may be formed to a second z-direction thickness (dimension D7). A third patterned masking layer may be formed over the back side of the semiconductor layer 1002, and the anti-reflection film 206c may be formed to a third z-direction thickness (dimension D8).

Additionally and/or alternatively, a layer of material may be deposited over the semiconductor layer 1002 to the third thickness (dimension D8), a patterned masking layer may be used to etch the portion of the layer of material over the photodiode 1004 of the pixel sensor 904b to form the anti-reflection film 206b from the layer of material to the second z-direction thickness (dimension D7). Another patterned masking layer may be used to etch the portion of the layer of material over the photodiode 1004 of the pixel sensor 904a to form the anti-reflection film 206a from the layer of material to the first z-direction thickness (dimension D6).

Additionally and/or alternatively, a first layer of material may be deposited above the photodiodes 1004 of the pixel sensors 904a-904c to the first z-direction thickness (dimension D6). A masking layer may be formed over a portion of the first layer above the photodiode 1004 of the pixel sensor 904a, and a second layer of material may be deposited above the photodiodes 1004 of the pixel sensors 904b and 904c such that a combined z-direction thickness of the first and second layers corresponds to the second z-direction thickness (dimension D7). Another masking layer may be formed over a portion of the second layer above the photodiode 1004 of the pixel sensor 904b, and a third layer of material may be deposited above the photodiodes 1004 of the pixel sensor 904c such that a combined z-direction thickness of the first, second, and third layers corresponds to the third z-direction thickness (dimension D8).

As shown in FIG. 11E, the isolation structure 1006 may be formed in the semiconductor layer 1002 such that the isolation structure 1006 laterally surrounds the photodiodes 1004 of the pixel sensors 904. Moreover, portions of the isolation structure 1006 may extend over the back side of the semiconductor layer 1002 such that the portions of the isolation structure 1006 are included on the anti-reflection films 206a-206c of the pixel sensors 904a-904c.

To form the isolation structure 1006, recesses may be formed into the semiconductor layer 1002 from the back side surface of the semiconductor layer 1002. In some implementations, a pattern in a photoresist layer is used to pattern the recesses. The recesses may include a plurality of interconnected trenches that extend into the semiconductor layer 1002 to form a grid around the photodiodes 1004 and, in some implementations, around the FD nodes 1008.

A deposition tool may be used to form the photoresist layer on the back side surface of the semiconductor layer 1002. An exposure tool may be used to expose the photoresist layer to a radiation source to pattern the photoresist layer. A developer tool may be used to develop and remove portions of the photoresist layer to expose the pattern. An etch tool may be used to etch the semiconductor layer 1002 based on the pattern to form the recesses. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses.

In some implementations, a cyclic etch technique is used to form the recesses to have a relatively high aspect ratio between the depth of the recesses and the lateral width of the recesses. For example, a cyclic etch technique is used to form the recesses such that the recesses have an aspect ratio between the depth of the recesses and the lateral width of the recesses that is at least approximately 8:1 or greater. However, other values for the aspect ratio of the recesses are within the scope of the present disclosure. The cyclic etch technique may include a plurality of deposition and etch cycles that are performed using protective liners to minimize lateral etching. For example, a deposition and etch cycle may include etching the recesses to a first depth in the semiconductor layer 1002, forming a protective liner on the sidewalls and bottom surface of the recesses, etching the protective liner to remove the protective liner from the bottom surface of the recesses, and etching the bottom of the recesses to increase the depth of the recesses to a second depth while the protective liner protects the sidewalls of the recesses from lateral etching. Additional cycles may be performed to achieve a particular depth for the recesses.

The recesses may be filled with one or more layers of material (e.g., a liner layer, a fill layer) to form the isolation structure 1006 in the recesses. A deposition tool may be used to deposit the one or more layers of the isolation structure 1006 using a PVD technique, an ALD technique, a CVD technique, an oxidation technique, and/or another type of deposition technique. In some implementations, a planarization tool may be used to perform a planarization operation (e.g., a CMP operation) to planarize the back side of the semiconductor layer 1002 to remove the material of the isolation structure 1006 from the back side surface of the semiconductor layer 1002. In some implementations, the planarization operation is omitted (or stops before the material of the isolation structure 1006 is removed from the back side surface of the semiconductor layer 1002) such that the material of the isolation structure 1006 remains on the back side surface of the semiconductor layer 1002.

As shown in FIG. 11F, the isolation grid 1018 may be formed above the backside surface of the semiconductor layer 1002. The isolation grid 1018 may be formed over the isolation structure 1006 such that the isolation grid 1018 conforms to the grid top view shape of the isolation structure 1006. A deposition tool may deposit the layer(s) of the isolation grid 1018 using a PVD technique, an ALD technique, a CVD technique, an oxidation technique, a plating technique (e.g., an electroplating technique, an electro-chemical plating technique), and/or another suitable deposition technique. In some implementations, a metal layer 1020 is deposited, and a dielectric layer 1022 is deposited on the metal layer 1020. A pattered masking layer may be formed above the dielectric layer 1022 and used to etch the metal layer 1020 and the dielectric layer 1022 to form the isolation grid 1018.

The color filters 1024 may be formed in the openings in the isolation grid 1018 above the photodiodes 1004. Moreover, the buffer layer 1026 may be formed above the color filters 1024, and the micro-lens structures 1028 may be formed or provided above the buffer layer 1026.

As indicated above, FIGS. 11A-11F are provided as an example. Other examples may differ from what is described with regard to FIGS. 11A-11F.

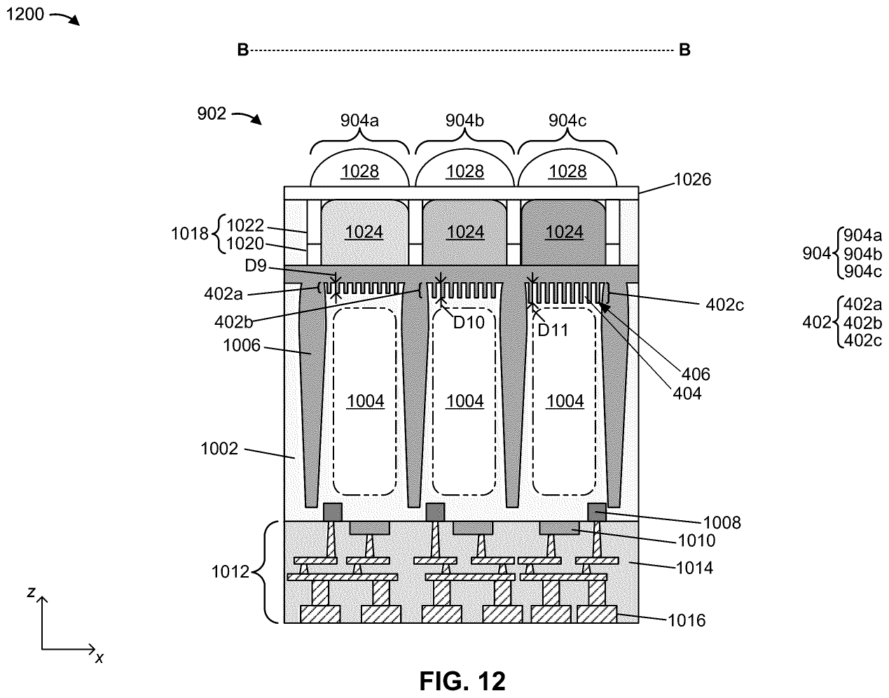

FIG. 12 is a diagram of an example implementation 1200 of a portion of the pixel sensor array 902 of the semiconductor device 900 described herein. As shown in FIG. 12, the pixel sensors 904a-904c of the pixel sensor array 902 included in the example implementation 1200 includes a similar combination and arrangement of layers and/or structures as the pixel sensors 904a-904c in the example implementation 1000 of the pixel sensor array 902 in FIG. 10. However, in the example implementation 1200 in FIG. 12, the pixel sensors 904a-904c include grating structures 402 as opposed to anti-reflection films 206.

As further shown in FIG. 12, two or more pixel sensors 904 may include separate grating structures 402. For example, a grating structure 402a may be included in the surface (e.g., the back side surface) of the semiconductor layer 1002 above the photodiode 1004 of the pixel sensor 904a, a grating structure 402b may be included in the surface (e.g., the back side surface) of the semiconductor layer 1002 above the photodiode 1004 of the pixel sensor 904b, a grating structure 402c may be included in the surface (e.g., the back side surface) of the semiconductor layer 1002 above the photodiode 1004 of the pixel sensor 904c, and so on.

As indicated above, the pixel sensors 904a-904c may include color filters 1024 that filter different wavelengths (or different wavelength ranges) of incident light. Accordingly, the grating structures 402a-402c may include gratings 404 that have different z-direction heights so that destructive interference reduces, minimizes, and/or prevents reflection of incident light for each of the different wavelengths (or different wavelength ranges) of incident light for the pixel sensors 904a-904c.

As an example of the above, the pixel sensor 904a may be a blue pixel sensor, the pixel sensor 904b may be a green pixel sensor, and the pixel sensor 904c may be a red pixel sensor. Thus, the photodiode 1004 of the pixel sensor 904a is configured to absorb incident light having the shortest wavelength of the pixel sensors 904a-904c, the photodiode 1004 of the pixel sensor 904c is configured to absorb incident light having the longest wavelength of the pixel sensors 904a-904c, and the photodiode 1004 of the pixel sensor 904b is configured to absorb incident light having a wavelength that is between the wavelengths sensed by the pixel sensors 904a and 904c. Accordingly, the z-direction heights of the gratings 404 of the grating structure 402a (indicated in FIG. 12 as dimension D9) may be less than the z-direction heights of the gratings 404 of the grating structure 402b (indicated in FIG. 12 as dimension D10) and the z-direction heights of the gratings 404 of the grating structure 402c (indicated in FIG. 12 as dimension D11). The z-direction heights of the gratings 404 of the grating structure 402b (dimension D10) may be greater than the z-direction heights of the gratings 404 of the grating structure 402a (dimension D9) and less than the z-direction heights of the gratings 404 of the grating structure 402c (dimension D11). The z-direction heights of the gratings 404 of the grating structure 402c (dimension D11) may be greater than the z-direction heights of the gratings 404 of the grating structure 402a (dimension D9) and the z-direction heights of the gratings 404 of the grating structure 402b (dimension D10).

As indicated above, FIG. 12 is provided as an example. Other examples may differ from what is described with regard to FIG. 12.

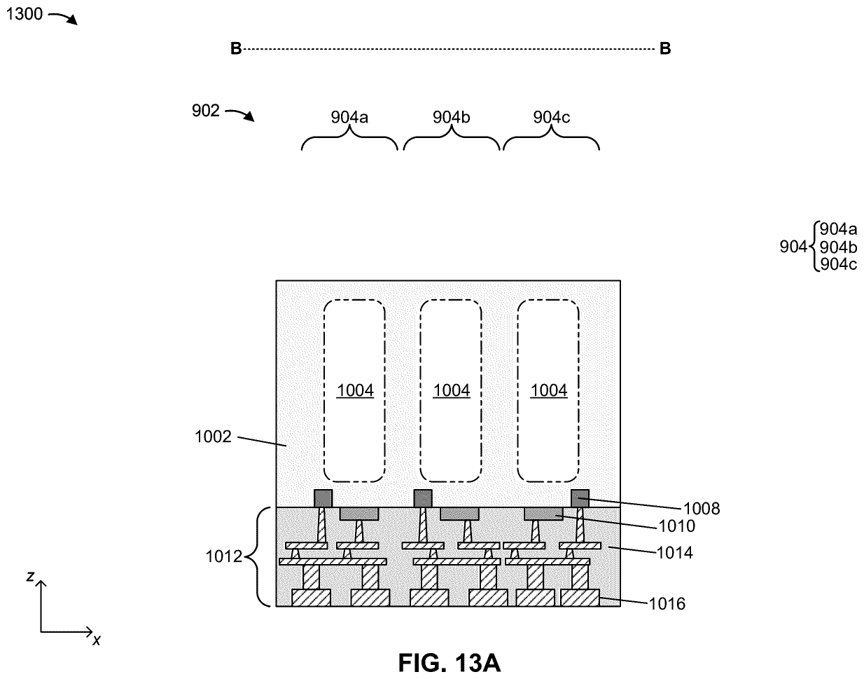

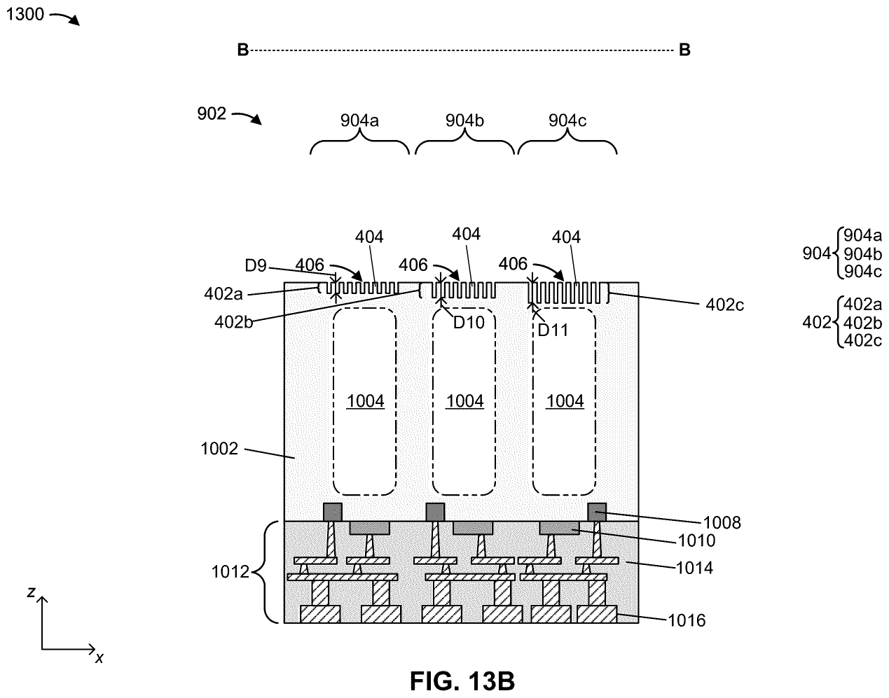

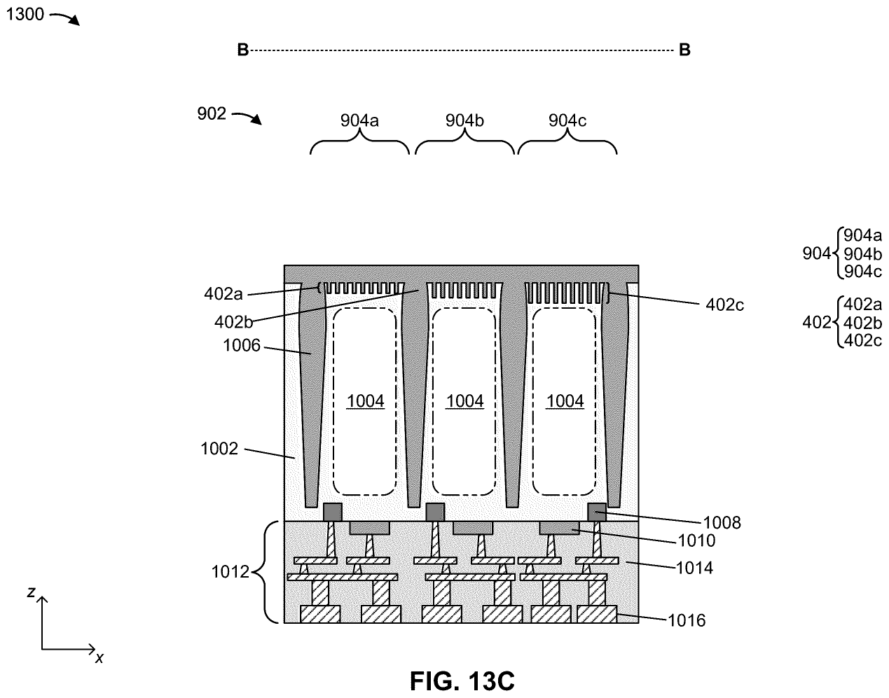

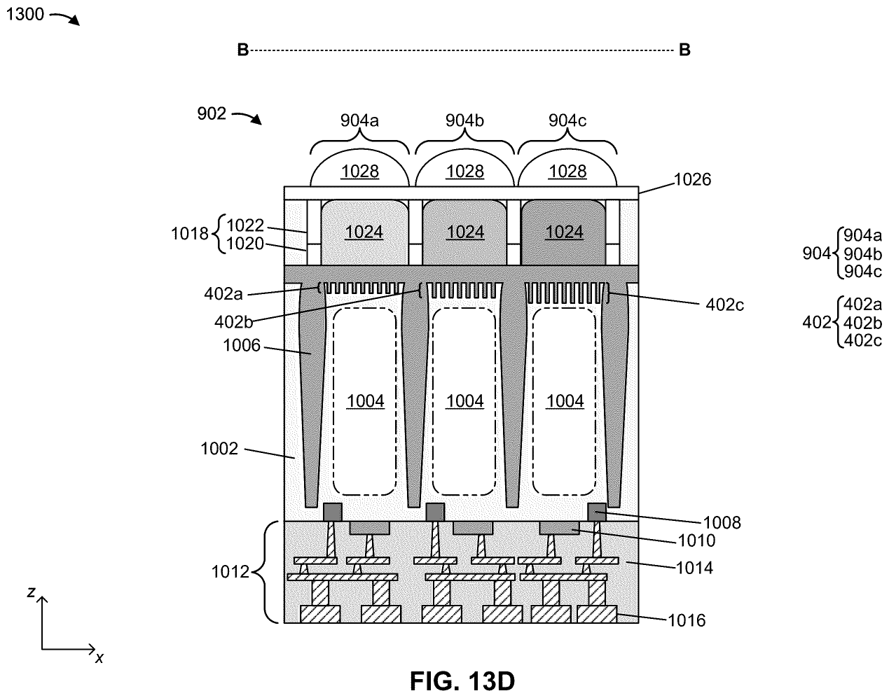

FIGS. 13A-13D are diagrams of an example implementation 1300 of forming a semiconductor device 900 described herein. In some implementations, one or more of the semiconductor processing operations described in connection with FIGS. 13A-13D may be performed using one or more semiconductor processing tools, such as a deposition tool, an exposure tool, a developer tool, an etch tool, a planarization tool, a plating tool, an ion implantation tool, and/or a bonding tool, among other examples.

As shown in FIG. 13A, one or more of the semiconductor processing operations described in connection with FIGS. 11A-11C may be performed to form the photodiodes 1004, the FD nodes 1008, the transfer gates 1010 of the pixel sensors 904 (e.g., the pixel sensors 904a-904c), and the dielectric layer(s) 1014 and the metallization layers 1016 of the interconnect layer 1012 of the semiconductor device 900.

As shown in FIG. 13B, the recesses 406 for the grating structures 402a-402c of the pixel sensors 902a-902c may be formed in the surface (e.g., the back side surface) of the semiconductor layer 1002. For example, the surface of the semiconductor layer 1002 above the photodiodes 1004 of the pixel sensors 904a-904c may etched to form the recesses 406 in the surface of the semiconductor layer 1002, where the gratings 404 of the grating structures 402a-402c define the recesses 406.

In some implementations, a pattern in a photoresist layer is used to etch the semiconductor layer 1002 to form the recesses 406 of the grating structures 402a-402c. In these implementations, a deposition tool may be used to form the photoresist layer on the semiconductor layer 1002 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the semiconductor layer 1002 based on the pattern to form the recesses 406. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 1002 based on a pattern.

The recesses 406 of the grating structure 402a may be formed to a z-direction depth such that the gratings 404 of the grating structure 402a have a z-direction height (e.g., dimension D9) that is based on the wavelength (or wavelength range) of incident light that is to be sensed by the photodiode 1004 of the pixel sensor 902a. The recesses 406 of the grating structure 402b may be formed to a z-direction depth such that the gratings 404 of the grating structure 402b have a z-direction height (e.g., dimension D10) that is based on the wavelength (or wavelength range) of incident light that is to be sensed by the photodiode 1004 of the pixel sensor 902b. The recesses 406 of the grating structure 402c may be formed to a z-direction depth such that the gratings 404 of the grating structure 402c have a z-direction height (e.g., dimension D11) that is based on the wavelength (or wavelength range) of incident light that is to be sensed by the photodiode 1004 of the pixel sensor 902c.

As shown in FIG. 13C, the isolation structure 1006 of the pixel sensor array 902 may be formed around the pixel sensors 904 in a similar manner as described in connection with FIG. 11E. Portions of the isolation structure 1006 formed above the back side surface of the semiconductor layer 1002 may be deposited in the recesses 406 between the gratings 404 of the grating structures 402a-402c.

As shown in FIG. 13D, the isolation grid 1018, the color filters 1024, the buffer layer 1026, and the micro-lens structures 1028 may be formed in a similar manner as described in connection with FIG. 11F.

As indicated above, FIGS. 13A-13D are provided as an example. Other examples may differ from what is described with regard to FIGS. 13A-13D.

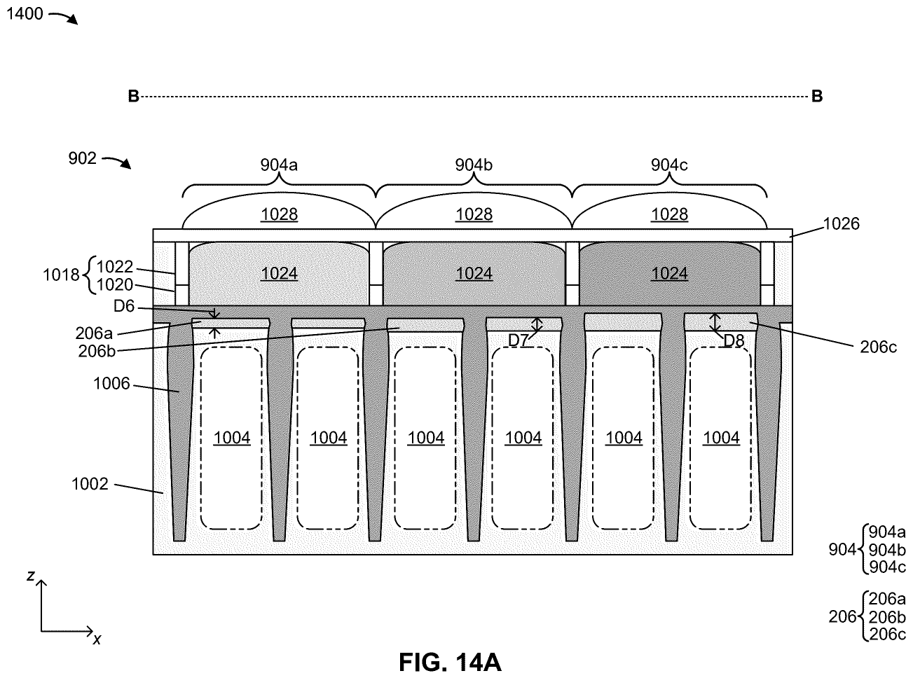

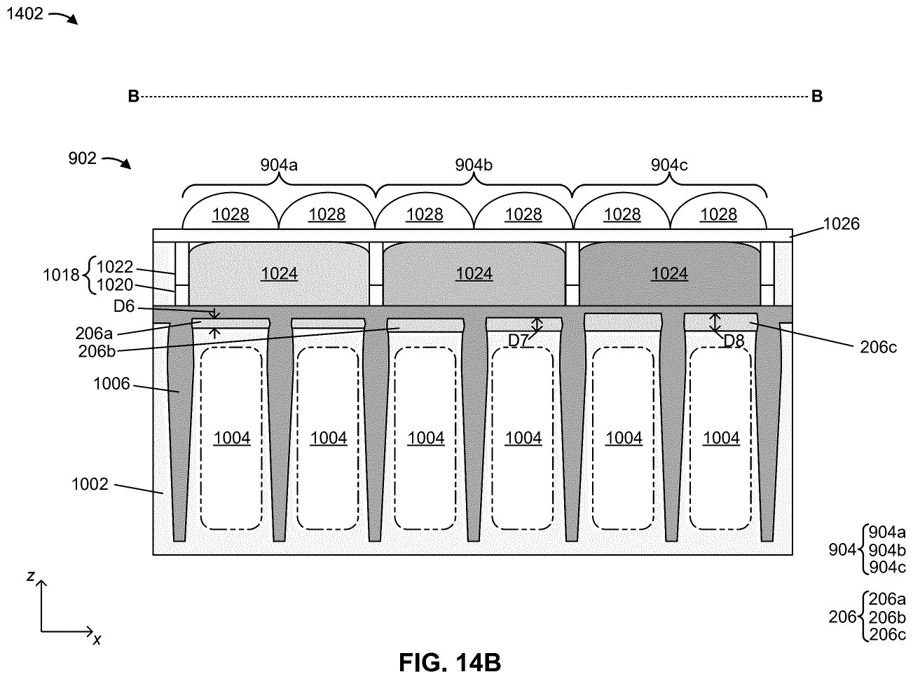

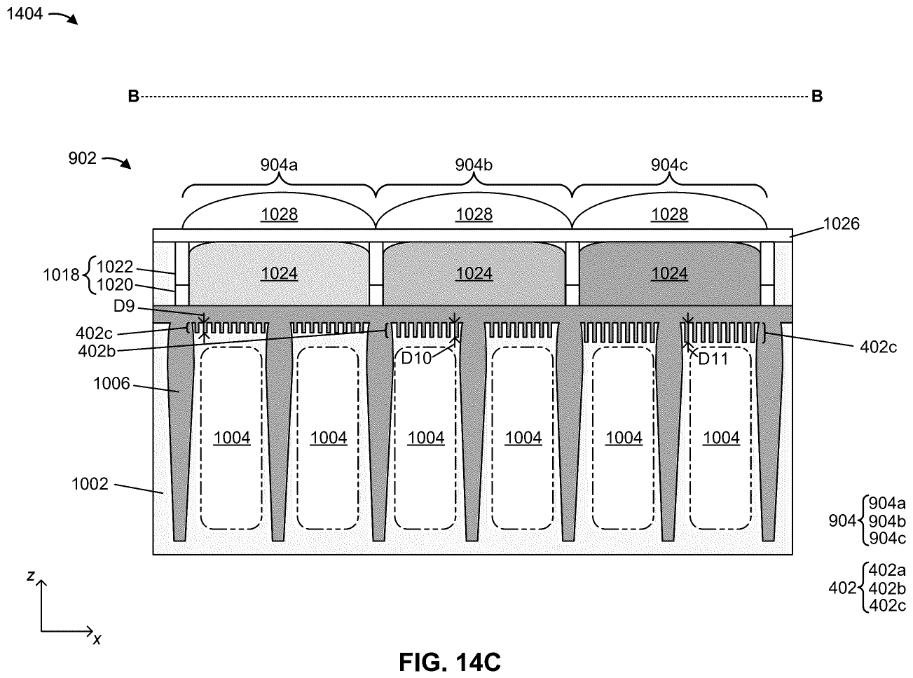

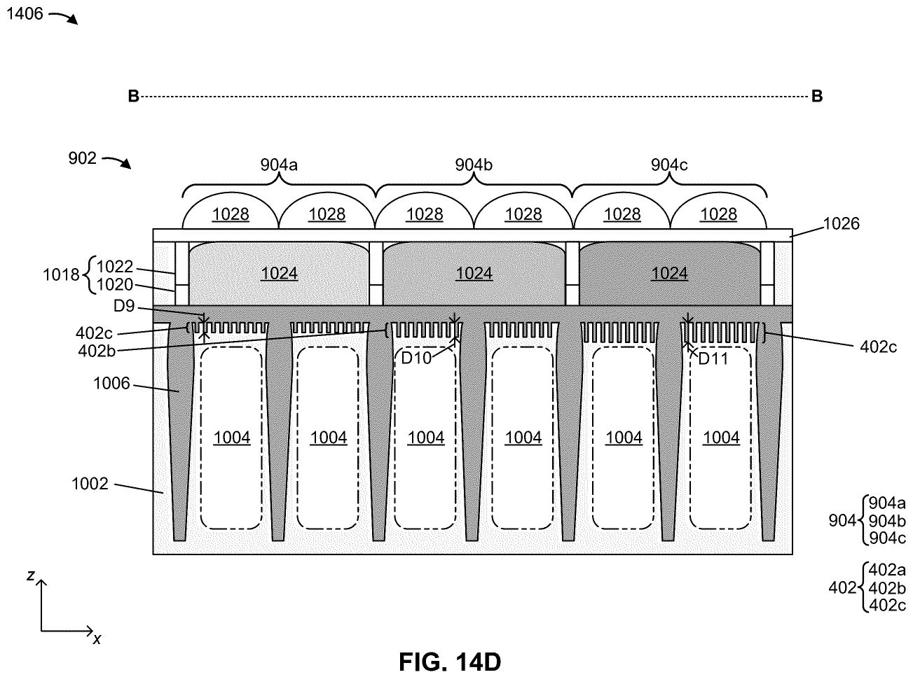

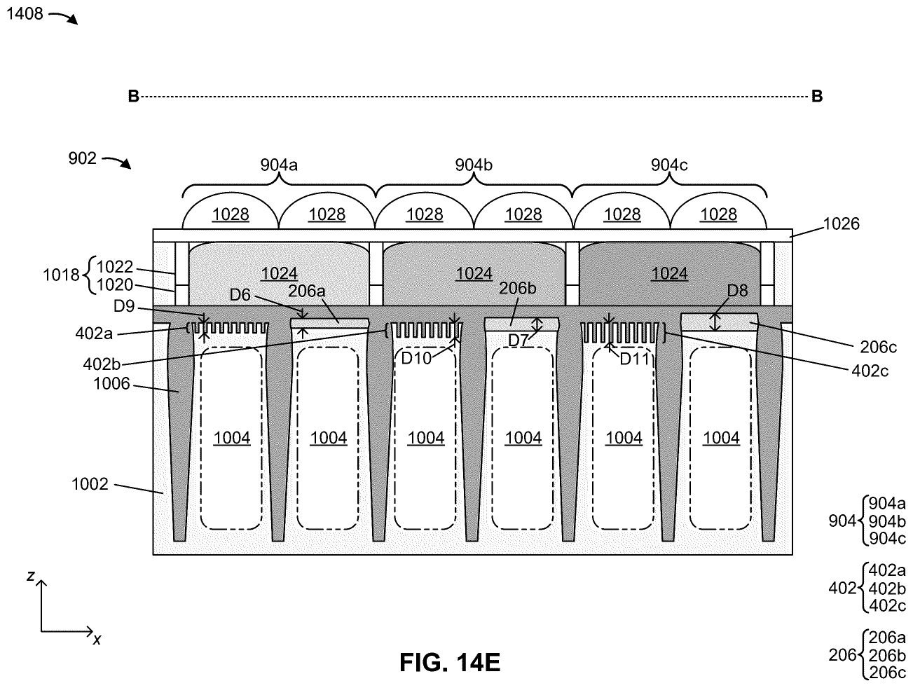

FIGS. 14A-14E are diagrams of additional example implementations of a portion of the pixel sensor array 902 of the semiconductor device 900 described herein.

FIG. 14A illustrates an example implementation 1400 of a portion of the pixel sensor array 902 of the semiconductor device 900. As shown in FIG. 14A, the pixel sensors 904a-904c of the pixel sensor array 902 in the example implementation 1400 include a similar combination and arrangement of layers and/or structures as the pixel sensors 904a-904c in the example implementation 1000 of the pixel sensor array 902 in FIG. 10. However, in the example implementation 1400 in FIG. 14A, the pixel sensors 904a-904c include a plurality of photodiodes 1004 that are shared by the same color filter 1024 and the same micro-lens structure 1028.

For example, the pixel sensor 904a may include a plurality of photodiodes 1004 (e.g., that may be optically isolated by the isolation structure 1006), a shared color filter 1024 over the photodiodes 1004, and a shared micro-lens structure 1028 over the color filter 1024. As another example, the pixel sensor 904b may include a plurality of photodiodes 1004 (e.g., that may be optically isolated by the isolation structure 1006), a shared color filter 1024 over the photodiodes 1004, and a shared micro-lens structure 1028 over the color filter 1024. As another example, the pixel sensor 904c may include a plurality of photodiodes 1004 (e.g., that may be optically isolated by the isolation structure 1006), a shared color filter 1024 over the photodiodes 1004, and a shared micro-lens structure 1028 over the color filter 1024.

As further shown in FIG. 14A, anti-reflection films 206a may be included over each of the photodiodes 1004 of the pixel sensor 902a. The anti-reflection films 206a may be spaced apart by the isolation structure 1006. Anti-reflection films 206b may be included over each of the photodiodes 1004 of the pixel sensor 902b. The anti-reflection films 206b may be spaced apart by the isolation structure 1006. The anti-reflection films 206a may each have a z-direction thickness (dimension D6) that is different than (e.g., less than) the z-direction thickness (dimension D7) of the anti-reflection films 206b. Anti-reflection films 206c may be included over each of the photodiodes 1004 of the pixel sensor 902c. The anti-reflection films 206c may be spaced apart by the isolation structure 1006. The anti-reflection films 206c may each have a z-direction thickness (dimension D8) that is different than (e.g., greater than) the z-direction thickness (dimension D7) of the anti-reflection films 206b and the z-direction thickness (dimension D6) of the anti-reflection films 206a.

FIG. 14B illustrates an example implementation 1402 of a portion of the pixel sensor array 902 of the semiconductor device 900. As shown in FIG. 14A, the pixel sensors 904a-904c of the pixel sensor array 902 in the example implementation 1402 include a similar combination and arrangement of layers and/or structures as the pixel sensors 904a-904c in the example implementation 1400 of the pixel sensor array 902 in FIG. 14A. However, in the example implementation 1402 in FIG. 14B, the pixel sensors 904a-904c each include a plurality of micro-lens structures 1028.

For example, the pixel sensor 904a may include a plurality of photodiodes 1004 (e.g., that may be optically isolated by the isolation structure 1006), a shared color filter 1024 over the photodiodes 1004, and a micro-lens structure 1028 for each of the photodiodes 1004. As another example, the pixel sensor 904b may include a plurality of photodiodes 1004 (e.g., that may be optically isolated by the isolation structure 1006), a shared color filter 1024 over the photodiodes 1004, and a micro-lens structure 1028 for each of the photodiodes 1004. As another example, the pixel sensor 904c may include a plurality of photodiodes 1004 (e.g., that may be optically isolated by the isolation structure 1006), a shared color filter 1024 over the photodiodes 1004, and a micro-lens structure 1028 for each of the photodiodes 1004.

As further shown in FIG. 14B, anti-reflection films 206a may be included over each of the photodiodes 1004 of the pixel sensor 902a, and separate micro-lens structures 1028 may be included over each of the anti-reflection films 206a. Anti-reflection films 206b may be included over each of the photodiodes 1004 of the pixel sensor 902b, and separate micro-lens structures 1028 may be included over each of the anti-reflection films 206b. Anti-reflection films 206c may be included over each of the photodiodes 1004 of the pixel sensor 902c, and separate micro-lens structures 1028 may be included over each of the anti-reflection films 206c.

FIG. 14C illustrates an example implementation 1404 of a portion of the pixel sensor array 902 of the semiconductor device 900. As shown in FIG. 14C, the pixel sensors 904a-904c of the pixel sensor array 902 in the example implementation 1404 include a similar combination and arrangement of layers and/or structures as the pixel sensors 904a-904c in the example implementation 1000 of the pixel sensor array 902 in FIG. 10. However, in the example implementation 1404 in FIG. 14C, the pixel sensors 904a-904c respectively include a plurality of grating structures 402a-402c as opposed to respectively including a plurality of anti-reflection films 206a-206c.

For example, grating structures 402a may be included over each of the photodiodes 1004 of the pixel sensor 902a. The grating structures 402a may be spaced apart by the isolation structure 1006. Grating structures 402b may be included over each of the photodiodes 1004 of the pixel sensor 902b. The grating structures 402b may be spaced apart by the isolation structure 1006. The gratings 404 of the grating structures 402a may each have a z-direction height (dimension D9) that is different than (e.g., less than) the z-direction height (dimension D10) of the gratings 404 of the grating structures 402b. Grating structures 402c may be included over each of the photodiodes 1004 of the pixel sensor 902c. The grating structures 402c may be spaced apart by the isolation structure 1006. The gratings 404 of the grating structures 402c may each have a z-direction height (dimension D11) that is different than (e.g., greater than) the z-direction height (dimension D10) of the gratings 404 of the grating structures 402b and the z-direction height (dimension D9) of the gratings 404 of the grating structures 402a.

FIG. 14D illustrates an example implementation 1406 of a portion of the pixel sensor array 902 of the semiconductor device 900. As shown in FIG. 14D, the pixel sensors 904a-904c of the pixel sensor array 902 in the example implementation 1406 include a similar combination and arrangement of layers and/or structures as the pixel sensors 904a-904c in the example implementation 1404 of the pixel sensor array 902 in FIG. 14C. However, in the example implementation 1406 in FIG. 14D, the pixel sensors 904a-904c each include a plurality of micro-lens structures 1028.

For example, the pixel sensor 904a may include a plurality of photodiodes 1004 (e.g., that may be optically isolated by the isolation structure 1006), a shared color filter 1024 over the photodiodes 1004, and a micro-lens structure 1028 for each of the photodiodes 1004. As another example, the pixel sensor 904b may include a plurality of photodiodes 1004 (e.g., that may be optically isolated by the isolation structure 1006), a shared color filter 1024 over the photodiodes 1004, and a micro-lens structure 1028 for each of the photodiodes 1004. As another example, the pixel sensor 904c may include a plurality of photodiodes 1004 (e.g., that may be optically isolated by the isolation structure 1006), a shared color filter 1024 over the photodiodes 1004, and a micro-lens structure 1028 for each of the photodiodes 1004.

As further shown in FIG. 14D, grating structures 402a may be included over each of the photodiodes 1004 of the pixel sensor 902a, and separate micro-lens structures 1028 may be included over each of the grating structures 402a. Grating structures 402b may be included over each of the photodiodes 1004 of the pixel sensor 902b, and separate micro-lens structures 1028 may be included over each of the grating structures 402b. Grating structures 402c may be included over each of the photodiodes 1004 of the pixel sensor 902c, and separate micro-lens structures 1028 may be included over each of the grating structures 402c.

FIG. 14E illustrates an example implementation 1408 of a portion of the pixel sensor array 902 of the semiconductor device 900. As shown in FIG. 14D, the pixel sensors 904a-904c of the pixel sensor array 902 in the example implementation 1408 include a similar combination and arrangement of layers and/or structures as the pixel sensors 904a-904c in the example implementation 1406 of the pixel sensor array 902 in FIG. 14D. However, in the example implementation 1408 in FIG. 14E, each of the pixel sensors 904a-904c includes a combination of an anti-reflection film 206 and a grating structure 402.

For example, the pixel sensor 904a may include a grating structure 402a over a first photodiode 1004 and an anti-reflection film 206a over a second photodiode 1004. The grating structure 402a and the anti-reflection film 206a may be spaced apart by the isolation structure 1006. In some implementations, the pixel sensor 904a includes a shared color filter 1024 and/or a shared micro-lens structure 1028 over the grating structure 402a and the anti-reflection film 206a. In some implementations, the pixel sensor 904a includes respective color filters 1024 and/or respective micro-lens structures 1028 over each of the grating structure 402a and the anti-reflection film 206a.

As another example, the pixel sensor 904b may include a grating structure 402b over a first photodiode 1004 and an anti-reflection film 206b over a second photodiode 1004. The grating structure 402b and the anti-reflection film 206b may be spaced apart by the isolation structure 1006. In some implementations, the pixel sensor 904b includes a shared color filter 1024 and/or a shared micro-lens structure 1028 over the grating structure 402b and the anti-reflection film 206b. In some implementations, the pixel sensor 904b includes respective color filters 1024 and/or respective micro-lens structures 1028 over each of the grating structure 402b and the anti-reflection film 206b.

As another example, the pixel sensor 904c may include a grating structure 402c over a first photodiode 1004 and an anti-reflection film 206c over a second photodiode 1004. The grating structure 402c and the anti-reflection film 206c may be spaced apart by the isolation structure 1006. In some implementations, the pixel sensor 904c includes a shared color filter 1024 and/or a shared micro-lens structure 1028 over the grating structure 402c and the anti-reflection film 206c. In some implementations, the pixel sensor 904c includes respective color filters 1024 and/or respective micro-lens structures 1028 over each of the grating structure 402c and the anti-reflection film 206c.

The anti-reflection film 206a may have a z-direction thickness (dimension D6) that is different than (e.g., less than) the z-direction thickness (dimension D7) of the anti-reflection film 206b. The anti-reflection films 206c may have a z-direction thickness (dimension D8) that is different than (e.g., greater than) the z-direction thickness (dimension D7) of the anti-reflection film 206b and the z-direction thickness (dimension D6) of the anti-reflection film 206a.

The gratings 404 of the grating structure 402a may each have a z-direction height (dimension D9) that is different than (e.g., less than) the z-direction height (dimension D10) of the gratings 404 of the grating structure 402b. The gratings 404 of the grating structure 402c may each have a z-direction height (dimension D11) that is different than (e.g., greater than) the z-direction height (dimension D10) of the gratings 404 of the grating structure 402b and the z-direction height (dimension D9) of the gratings 404 of the grating structure 402a.

As indicated above, FIGS. 14A-14E are provided as examples. Other examples may differ from what is described with regard to FIGS. 14A-14E.

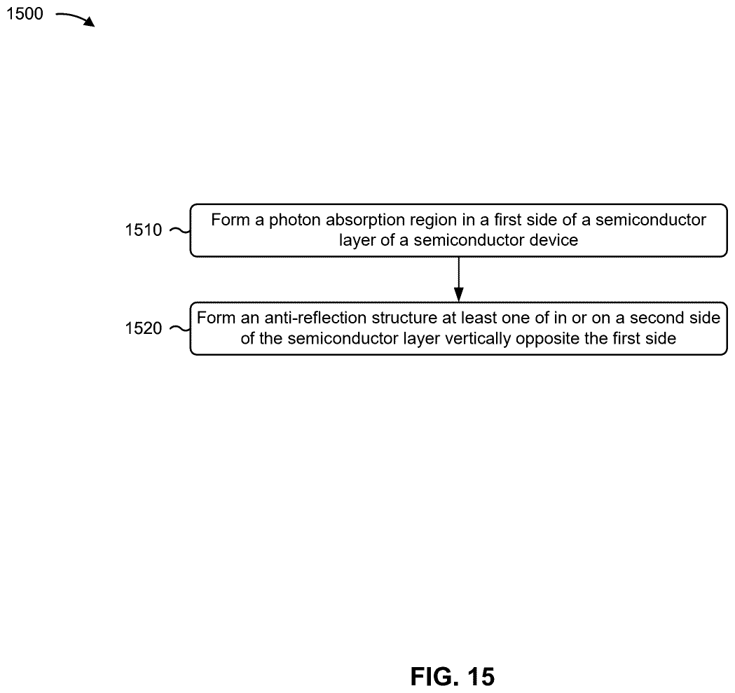

FIG. 15 is a flowchart of an example process 1500 associated with forming a semiconductor device described herein. In some implementations, one or more process blocks of FIG. 15 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 15, process 1500 may include forming a photon absorption region in a first side of a semiconductor layer of a semiconductor device (block 1510). For example, one or more semiconductor processing tools may be used to form a photon absorption region (e.g., a photon absorption region 204, a photodiode 1004) in a first side of a semiconductor layer (e.g., a semiconductor layer 202, a semiconductor layer 1002) of a semiconductor device (e.g., a semiconductor device 100, a semiconductor device 900), as described herein.

As further shown in FIG. 15, process 1500 may include forming an anti-reflection structure at least one of in or on a second side of the semiconductor layer vertically opposite the first side (block 1520). For example, one or more semiconductor processing tools may be used to form an anti-reflection structure (e.g., an anti-reflection film 206, a grating structure 402) at least one of in or on a second side of the semiconductor layer vertically opposite the first side, as described herein. In some implementations, the anti-reflection structure is formed to a thickness (e.g., a dimension D1, a dimension D6, a dimension D7, a dimension D8, a dimension D9, a dimension D10, a dimension D11) that is based on a wavelength of light that is to be sensed by the photon absorption region.

Process 1500 may include additional implementations, such as any single implementation or any combination of implementations described below and/or in connection with one or more other processes described elsewhere herein.

In a first implementation, forming the anti-reflection structure includes forming an anti-reflection film (e.g., an anti-reflection film 206) on the second side of the semiconductor layer, wherein the thickness of the anti-reflection structure is based on a refractive index of a material of the anti-reflection film.

In a second implementation, alone or in combination with the first implementation, the refractive index of the material of the anti-reflection film is less than a refractive index of a material of the semiconductor layer.

In a third implementation, alone or in combination with one or more of the first and second implementations, forming the photon absorption region includes forming another anti-reflection structure (e.g., a grating structure 602) in the photon absorption region.

In a fourth implementation, alone or in combination with one or more of the first through third implementations, the anti-reflection structure and the other anti-reflection structure comprise different materials.

In a fifth implementation, the process 1500 further includes forming a micro-lens structure (e.g., a micro-lens structure 210, a micro-lens structure 1028) above the anti-reflection structure such that the photon absorption region, the anti-reflection structure, and the micro-lens structure are vertically aligned in the semiconductor device.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

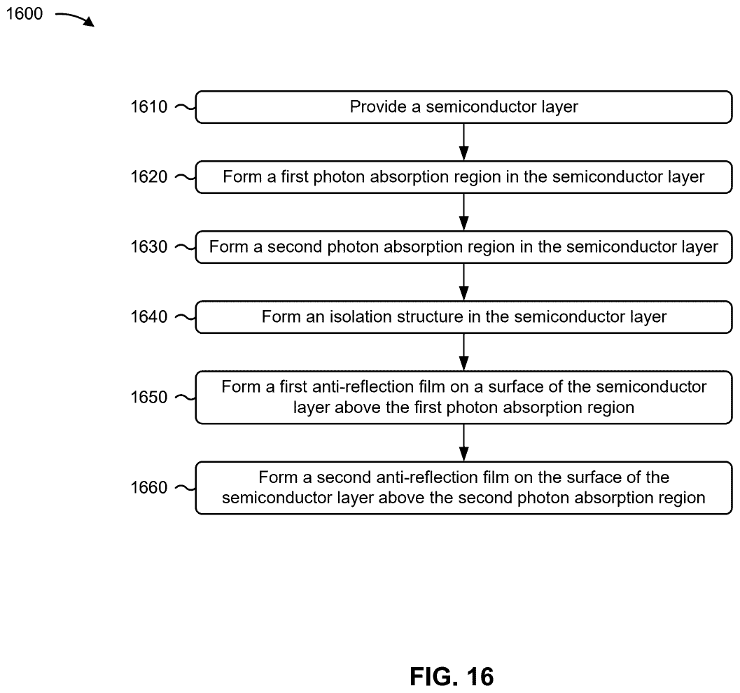

FIG. 16 is a flowchart of an example process 1600 associated with forming a semiconductor devices described herein. In some implementations, one or more process blocks of FIG. 16 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 16, process 1600 may include providing a semiconductor layer (block 1610). For example, one or more semiconductor processing tools may be used to provide a semiconductor layer, as described herein.

As further shown in FIG. 16, process 1600 may include forming a first photon absorption region in the semiconductor layer (block 1620). For example, one or more semiconductor processing tools may be used to form a first photon absorption region in the semiconductor layer, as described herein.

As further shown in FIG. 16, process 1600 may include forming a second photon absorption region in the semiconductor layer (block 1630). For example, one or more semiconductor processing tools may be used to form a second photon absorption region in the semiconductor layer, as described herein.

As further shown in FIG. 16, process 1600 may include forming an isolation structure in the semiconductor layer (block 1640). For example, one or more semiconductor processing tools may be used to form an isolation structure in the semiconductor layer, as described herein. In some implementations, the isolation structure laterally surrounds the first photon absorption region and laterally surrounds the second photon absorption region.

As further shown in FIG. 16, process 1600 may include forming a first anti-reflection film on a surface of the semiconductor layer above the first photon absorption region (block 1650). For example, one or more semiconductor processing tools may be used to form a first anti-reflection film on a surface of the semiconductor layer above the first photon absorption region, as described herein. In some implementations, the first anti-reflection film is formed to have a first thickness that is based on a first wavelength of incident light that the first photon absorption region is to sense.

As further shown in FIG. 16, process 1600 may include forming a second anti-reflection film on the surface of the semiconductor layer above the second photon absorption region (block 1660). For example, one or more semiconductor processing tools may be used to form a second anti-reflection film on the surface of the semiconductor layer above the second photon absorption region, as described herein. In some implementations, the second anti-reflection film is formed to have a second thickness that is based on a second wavelength of incident light that the second photon absorption region is to sense. In some implementations, the first thickness and the second thickness are different thicknesses.

Process 1600 may include additional implementations, such as any single implementation or any combination of implementations described below and/or in connection with one or more other processes described elsewhere herein.

In a first implementation, process 1600 includes forming a first color filter above the first micro-lens structure, where the first color filter includes a first material composition that is transmissive for the first wavelength range of incident light, and forming a second color filter above the second micro-lens structure, where the second color filter includes a second material composition that is transmissive for the second wavelength range of incident light forming a first micro-lens structure above the first color filter, and forming a second micro-lens structure above the second color filter, where the first anti-reflection film is between the first micro-lens structure and the first photon absorption region, and where the second anti-reflection film is between the second micro-lens structure and the second photon absorption region.

In a second implementation, alone or in combination with the first implementation, process 1600 includes forming a third photon absorption region in the semiconductor layer, forming a third anti-reflection film on the surface of the semiconductor layer, where the first micro-lens structure is formed above the third photon absorption region, and where the third anti-reflection film is between the first micro-lens structure and the third photon absorption region, where the third anti-reflection film has a third thickness, and where the first thickness and the third thickness are approximately a same thickness.

In a third implementation, alone or in combination with one or more of the first and second implementations, process 1600 includes forming a third photon absorption region in the semiconductor layer, forming a third anti-reflection film on the surface of the semiconductor layer above the third photon absorption region, and forming a third micro-lens structure above the third anti-reflection film, where the third anti-reflection film has a third thickness, and where the first thickness and the third thickness are approximately a same thickness.

In a fourth implementation, alone or in combination with one or more of the first through third implementations, process 1600 includes forming a third photon absorption region in the semiconductor layer, forming a grating structure across a region of the surface of the semiconductor layer that is above the third photon absorption region, where the grating structure includes a plurality of gratings, and where portions of the region of the semiconductor layer are located between adjacent pairs of the plurality of gratings, and a third micro-lens structure above the grating structure.

In a fifth implementation, alone or in combination with one or more of the first through fourth implementations, the first anti-reflection film is located between the surface of the semiconductor layer and a first optical spacer structure, and wherein the second anti-reflection film is located between the surface of the semiconductor layer and a second optical spacer structure.

In a sixth implementation, alone or in combination with one or more of the first through fifth implementations, the first photon absorption region includes a grating structure across a surface of the first photon absorption region, wherein the grating structure includes a plurality of gratings facing the surface of the semiconductor layer, and wherein portions of the semiconductor layer are located between adjacent pairs of the plurality of gratings.

Although FIG. 16 shows example blocks of process 1600, in some implementations, process 1600 includes additional blocks, fewer blocks, different blocks, or differently arranged blocks than those depicted in FIG. 16. Additionally, or alternatively, two or more of the blocks of process 1600 may be performed in parallel.

In this way, a semiconductor optical sensor structure of a semiconductor device may include a photon absorption region and an anti-reflection structure (e.g., an anti-reflection film, a grating structure) above the photon absorption region. The anti-reflection structure may be tuned for the semiconductor optical sensor structure to achieve minimal reflection of incident light. In particular, attributes such as film thickness, refractive index, grating height, grating half-pitch, grating width, and/or grating spacing (among other examples) of the anti-reflection structure may be tuned to achieve a high percentage of transmittance of incident light (e.g., a high percentage of photons of the incident light that propagate through to the photon absorption region of the semiconductor optical sensor structure) and/or may be tuned to achieve destructive interference for incident light that is reflected.

As described in greater detail above, some implementations described herein provide a semiconductor device. The semiconductor device includes a semiconductor layer. The semiconductor device includes a first photon absorption region in the semiconductor layer. The semiconductor device includes a second photon absorption region in the semiconductor layer. The semiconductor device includes an isolation structure laterally surrounding the first photon absorption region and laterally surrounding the second photon absorption region. The semiconductor device includes a first micro-lens structure above the first photon absorption region. The semiconductor device includes a second micro-lens structure above the second photon absorption region. The semiconductor device includes a first anti-reflection film on a surface of the semiconductor layer, where the first anti-reflection film is between the first micro-lens structure and the first photon absorption region, and where the first anti-reflection film has a first thickness. The semiconductor device includes a second anti-reflection film on the surface of the semiconductor layer, where the second anti-reflection film is between the second micro-lens structure and the second photon absorption region, where the second anti-reflection film has a second thickness, and where the first thickness and the second thickness are different thicknesses.

As described in greater detail above, some implementations described herein provide a semiconductor device. The semiconductor device includes a semiconductor layer. The semiconductor device includes a photon absorption region in the semiconductor layer. The semiconductor device includes an isolation structure laterally surrounding the photon absorption region. The semiconductor device includes a micro-lens structure above the photon absorption region. The semiconductor device includes a grating structure across a surface of the photon absorption region that is facing the micro-lens structure, where the grating structure includes a plurality of gratings that are spaced apart by portions of the semiconductor layer.

As described in greater detail above, some implementations described herein provide a method. The method includes forming a photon absorption region in a first side of a semiconductor layer of a semiconductor device. The method includes forming an anti-reflection structure at least one of in or on a second side of the semiconductor layer vertically opposite the first side, where the anti-reflection structure is formed to a thickness that is based on a wavelength of light that is to be sensed by the photon absorption region. The method includes forming a micro-lens structure above the anti-reflection structure such that the photon absorption region, the anti-reflection structure, and the micro-lens structure are vertically aligned in the semiconductor device.

As described in greater detail above, some implementations described herein include a method. The method includes providing a semiconductor layer. The method includes forming a first photon absorption region in the semiconductor layer. The method includes forming a second photon absorption region in the semiconductor layer. The method includes forming an isolation structure in the semiconductor layer. The isolation structure laterally surrounds the first photon absorption region and laterally surrounds the second photon absorption region. The method includes forming a first anti-reflection film on a surface of the semiconductor layer above the first photon absorption region. The first anti-reflection film is formed to have a first thickness that is based on a first wavelength of incident light that the first photon absorption region is to sense. The method includes forming a second anti-reflection film on the surface of the semiconductor layer above the second photon absorption region. The second anti-reflection film is formed to have a second thickness that is based on a second wavelength of incident light that the second photon absorption region is to sense. The first thickness and the second thickness are different thicknesses.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a semiconductor layer;
forming a first photon absorption region in the semiconductor layer;
forming a second photon absorption region in the semiconductor layer;
forming an isolation structure in the semiconductor layer;
wherein the isolation structure laterally surrounds the first photon absorption region and laterally surrounds the second photon absorption region;
forming a first anti-reflection film on a surface of the semiconductor layer above the first photon absorption region,
wherein the first anti-reflection film is formed to have a first thickness that is based on a first wavelength of incident light that the first photon absorption region is to sense; and
forming a second anti-reflection film on the surface of the semiconductor layer above the second photon absorption region,
wherein the second anti-reflection film is formed to have a second thickness that is based on a second wavelength of incident light that the second photon absorption region is to sense, and
wherein the first thickness and the second thickness are different thicknesses.

2. The method of claim 1, further comprising:
forming a first color filter above the first anti-reflection film,
wherein the first color filter includes a first material composition that is transmissive for the first wavelength of incident light; and
forming a second color filter above the second anti-reflection film,
wherein the second color filter includes a second material composition that is transmissive for the second wavelength of incident light;
forming a first micro-lens structure above the first color filter; and
forming a second micro-lens structure above the second color filter,
wherein the first anti-reflection film is between the first micro-lens structure and the first photon absorption region, and
wherein the second anti-reflection film is between the second micro-lens structure and the second photon absorption region.

3. The method of claim 2, further comprising:
forming a third photon absorption region in the semiconductor layer,
forming a third anti-reflection film on the surface of the semiconductor layer,
wherein the first micro-lens structure is formed above the third photon absorption region; and
wherein the third anti-reflection film is between the first micro-lens structure and the third photon absorption region,
wherein the third anti-reflection film has a third thickness, and
wherein the first thickness and the third thickness are approximately a same thickness.

4. The semiconductor device of claim 2, further comprising:
forming a third photon absorption region in the semiconductor layer;
forming a third anti-reflection film on the surface of the semiconductor layer above the third photon absorption region; and
forming a third micro-lens structure above the third anti-reflection film,
wherein the third anti-reflection film has a third thickness, and
wherein the first thickness and the third thickness are approximately a same thickness.

5. The semiconductor device of claim 2, further comprising:
forming a third photon absorption region in the semiconductor layer;
forming a grating structure across a region of the surface of the semiconductor layer that is above the third photon absorption region,
wherein the grating structure comprises a plurality of gratings, and
wherein portions of the region of the semiconductor layer are located between adjacent pairs of the plurality of gratings; and
forming a third micro-lens structure above the grating structure.

6. The semiconductor device of claim 1, wherein the first anti-reflection film is located between the surface of the semiconductor layer and a first optical spacer structure; and
wherein the second anti-reflection film is located between the surface of the semiconductor layer and a second optical spacer structure.

7. The semiconductor device of claim 1, wherein the first photon absorption region comprises a grating structure across a surface of the first photon absorption region,
wherein the grating structure comprises a plurality of gratings facing the surface of the semiconductor layer, and
wherein portions of the semiconductor layer are located between adjacent pairs of the plurality of gratings.

8. A semiconductor device, comprising:
a semiconductor layer;
a photon absorption region in the semiconductor layer;
an isolation structure laterally surrounding the photon absorption region;
a grating structure across a surface of the photon absorption region that is facing a surface of the semiconductor layer,
wherein the grating structure comprises a plurality of gratings that are spaced apart by portions of the semiconductor layer.

9. The semiconductor device of claim 8, further comprising:
a micro-lens structure above the photon absorption region; and
an anti-reflection film directly on the surface of the semiconductor layer,
wherein the anti-reflection film is vertically between the grating structure and the micro-lens structure, and
wherein the anti-reflection film comprises a high dielectric constant (high-k) dielectric material.

10. The semiconductor device of claim 8, further comprising:
another grating structure across a region of the surface of the semiconductor layer that is above the photon absorption region,
wherein the other grating structure comprises another plurality of gratings, and
wherein portions of the region of the semiconductor layer are located between adjacent pairs of the other plurality of gratings.

11. The semiconductor device of claim 8, further comprising:
another photon absorption region in the semiconductor layer; and
another grating structure across a surface of the other photon absorption region,
wherein the other grating structure comprises another plurality of gratings that are spaced apart by other portions of the semiconductor layer, and
wherein a first height of the plurality of gratings is greater than a second height of the other plurality of gratings.

12. The semiconductor device of claim 8, further comprising:
another photon absorption region in the semiconductor layer; and
another grating structure across a region of the surface of the semiconductor layer that is above the other photon absorption region,
wherein the other grating structure comprises another plurality of gratings, and
wherein portions of the region of the semiconductor layer are located between adjacent pairs of the other plurality of gratings.

13. The semiconductor device of claim 8, further comprising:
another photon absorption region in the semiconductor layer; and
an anti-reflection film directly on the surface of the semiconductor layer,
wherein the anti-reflection film is above the other photon absorption region.

14. The semiconductor device of claim 8, further comprising:
a first anti-reflection film directly on the surface of the semiconductor layer,
wherein the first anti-reflection film is above the photon absorption region, and
wherein the first anti-reflection film has a first thickness, and a second anti-reflection film directly on the surface of the semiconductor layer,
wherein the second anti-reflection film is above another photon absorption region,
wherein the second anti-reflection film has a second thickness, and
wherein the first thickness and the second thickness are different thicknesses.

15. The semiconductor device of claim 8, wherein the semiconductor layer comprises silicon (Si); and
wherein the photon absorption region comprises germanium (Ge).

16. A method, comprising:
forming a photon absorption region in a first side of a semiconductor layer of a semiconductor device;
forming an anti-reflection structure at least one of in or on a second side of the semiconductor layer vertically opposite the first side,
wherein the anti-reflection structure is formed to a thickness that is based on a wavelength of light that is to be sensed by the photon absorption region.

17. The method of claim 16, wherein forming the anti-reflection structure comprises:
forming an anti-reflection film on the second side of the semiconductor layer,
wherein the thickness of the anti-reflection structure is based on a refractive index of a material of the anti-reflection film; and
wherein the method further comprises:
forming a micro-lens structure above the anti-reflection structure such that the photon absorption region, the anti-reflection structure, and the micro-lens structure are vertically aligned in the semiconductor device.

18. The method of claim 17, wherein the refractive index of the material of the anti-reflection film is less than a refractive index of a material of the semiconductor layer.

19. The method of claim 16, wherein forming the photon absorption region comprises:
forming another anti-reflection structure in the photon absorption region.

20. The method of claim 19, wherein the anti-reflection structure and the other anti-reflection structure comprise different materials.
